(19) United States
(12) Patent Application Publication
(10) Pub. No.: US 2026/0113949 A1
(43) Pub. Date: Apr. 23, 2026

(54) MEMORY DEVICE INCLUDING PLURALITY OF STRING SELECTION LINES

(71) Applicant: Samsung Electronics Co., Ltd., Suwon-si (KR)

(72) Inventors: Hanmin Nam, Suwon-si (KR); Jeunghwan Park, Suwon-si (KR)

(21) Appl. No.: 19/312,662

(22) Filed: Aug. 28, 2025

(30) Foreign Application Priority Data
Oct. 18, 2024 (KR) 10-2024-0142967

(51) Int. Cl. H10B 43/35; H10B 43/10; H10B 43/27

(52) U.S. Cl. CPC H10B 43/35; H10B 43/10; H10B 43/27

(57) ABSTRACT

A memory device includes a first word line cut, a second word line cut, a first sub array, a second sub array, and a plurality of string selection lines associated with each sub array respectively. A first-sub-array first string selection line is spaced apart from the first word line cut by a first length and a first-sub-array second string selection line is spaced apart from the first word line cut by a second length greater than the first length. A second-sub-array first string selection line is spaced apart from the second word line cut by the second length and is connected to the first-sub-array first string selection line. A second-sub-array second string selection line is connected to the first-sub-array second string selection line.

### CROSS-REFERENCE TO RELATED APPLICATION

This application claims priority to and the benefit of Korean Patent Application No. 10-2024-0142967 filed in the Korean Intellectual Property Office on Oct. 18, 2024, the entire contents of which are incorporated herein by reference.

### BACKGROUND

A memory device is used to store data and is classified into a volatile memory device and a non-volatile memory device. In response to demands for higher capacity and small non-volatile memory devices, a three-dimensional memory device has been developed, which includes multiple channel holes extending vertically on a substrate. In order to improve the integration density of a three-dimensional memory device, the number of channel holes included in each memory block may be increased. In the non-volatile memory device having such a multi hole structure, performance may vary due to differences in the intrinsic characteristics of the channel holes.

### SUMMARY

Implementations are for a memory device including a plurality of string selection lines having a constant distance from a word line cut.

According to some implementations, a memory device includes a first sub array including a first word line cut, a second word line cut, and a plurality of string selection line cuts positioned between the first word line cut and the second word line cut, and a second sub array including a third word line cut, a fourth word line cut, and a plurality of string selection line cuts positioned between the third word line cut and the fourth word line cut. The first sub array includes a first string selection line of the first sub array positioned between the first word line cut and a first string selection line cut of the first sub array among the plurality of string selection line cuts of the first sub array, where the distance to the first word line cut corresponds to the first length; and a second string selection line of the first sub array positioned between the first string selection line cut of the first sub array and a second string selection line cut of the first sub array among the plurality of string selection line cuts of the first sub array, where the distance to the first word line cut is farther than the distance to the first string selection line cut of the first sub array. The second sub array includes a first string selection line of the second sub array positioned between a first string selection line cut of the second sub array, among the plurality of string selection line cuts in the second sub array, where the distance to the third word line cut corresponds to the second length, and a second string selection line cut of the second sub array where the distance to the third word line cut is farther than the distance to the first string selection line cut of the second sub array and connected to the first string selection line of the first sub array; and a second string selection line of the second sub array positioned between the third word line cut and the first string selection line cut of the second sub array and connected to the second string selection line of the first sub array.

The memory device according to some implementations includes a first word line cut, a second word line cut, a third word line cut, a fourth word line cut, a first string selection line of a first sub array positioned between the first word line cut and the second word line cut, where a distance between the adjacent word line cut among the first word line cut and the second word line cut corresponds to the first length, a second string selection line of the first sub array positioned between the first word line cut and the second word line cut, where a distance between the adjacent word line cut among the first word line cut and the second word line cut corresponds to a second length which is farther than the first length, a first string selection line of the second sub array, positioned between the third word line cut and the fourth word line cut, where a distance between the adjacent word line cut among the third word line cut and the fourth word line cut corresponds to the second length, and connected to the first string selection line of the first sub array, and a second string selection line of the second sub array, positioned between the third word line cut and the fourth word line cut, where a distance between the adjacent word line cut among the third word line cut and the fourth word line cut corresponds to the first length, and connected to the second string selection line of the first sub array.

According to some implementations, a memory device includes a first sub array comprising a first word line cut, a second word line cut, and a plurality of string selection lines positioned between the first word line cut and the second word line cut; and a second sub array comprising a third word line cut, a fourth word line cut, and a plurality of string selection lines positioned between the third word line cut and the fourth word line cut. Each of the plurality of string selection lines of the first sub array is connected to each of the plurality of string selection lines of the second sub array, and the sum of a first length corresponding to a distance between the first string selection line of the first sub array adjacent to the first word line cut among the plurality of string selection lines of the first sub array and the first word line cut, and a second length corresponding to a distance between the first string selection line of the second sub array connected to the first string selection line of the first sub array among the plurality of string selection lines of the second sub array and the adjacent word line cut among the third word line cut and the fourth word line cut is equal to the sum of a third length corresponding to the distance between the second string selection line of the first sub array and the adjacent word line cut among the first word line cut and the second word line cut among the plurality of string selection lines of the first sub array, and a fourth length corresponding to the distance between the second string selection line of the second sub array connected to the second string selection line of the first sub array and the adjacent word line cut among the third word line cut and the fourth word line cut among the plurality of string selection lines of the second sub array.

### BRIEF DESCRIPTION OF THE DRAWINGS

FIG. 1 is a diagram illustrating a non-volatile memory device according to some implementations.

FIG. 2 is a diagram illustrating a plurality of sub arrays including a plurality of memory blocks according to some implementations.

FIG. 3 is a circuit diagram illustrating a sub block according to some implementations.

FIG. 4 is a perspective view illustrating a sub block according to some implementations.

FIG. 5 is a cross-sectional view illustrating a sub block according to some implementations.

FIG. 6 is a plan view illustrating a memory block according to some implementations.

FIG. 7 is a drawing for explaining the connection relationship among three string selection lines included in each of a plurality of sub blocks according to some implementations.

FIG. 8 is a drawing for explaining another example of a connection relationship between three string selection lines each included in a plurality of sub blocks according to some implementations.

FIG. 9 is a drawing for explaining the connection relationship among four string selection lines included in each of a plurality of sub blocks according to some implementations.

FIG. 10 is a drawing for explaining another example of a connection relationship among four string selection lines each included in a plurality of sub blocks according to some implementations.

FIG. 11 is a drawing for explaining the connection relationship among five string selection lines included in each of a plurality of sub blocks according to some implementations.

FIG. 12 is a drawing for explaining the connection relationship among six string selection lines included in each of a plurality of sub blocks according to some implementations.

FIG. 13 is a drawing for explaining another example of multiple sub blocks according to some implementations.

FIG. 14 is a drawing for explaining the connection relationship among eight string selection lines included in each of a plurality of sub blocks according to some implementations.

FIG. 15 is a diagram for explaining a connection relationship between a plurality of sub blocks and a row decoder according to some implementations.

FIG. 16 is a diagram illustrating another example of a connection relationship between a plurality of sub blocks and a row decoder according to some implementations.

FIG. 17 is a diagram illustrating another example of a connection relationship between a plurality of sub blocks and a row decoder according to some implementations.

FIG. 18 is a diagram illustrating another example of a plurality of sub arrays including a plurality of memory blocks according to some implementations.

FIG. 19 is a diagram illustrating another example of a connection relationship between a plurality of sub blocks and a row decoder according to some implementations.

FIG. 20 is a cross-sectional view illustrating a non-volatile memory device having a B-VNAND (Bonding Vertical NAND) structure according to some implementations.

FIG. 21 is a drawing for explaining a storage device including a non-volatile memory device according to some implementations.

### DETAILED DESCRIPTION

Hereinafter, various implementations of the present disclosure will be described in detail with reference to the accompanying drawings so that those skilled in the art may easily implement the present disclosure. The present disclosure may be implemented in several different forms and is not limited to the implementations described herein.

In order to clearly explain the present disclosure, parts that do not have a relationship with the explanation are omitted, and identical or similar component is assigned the same reference numerals throughout the specification.

In addition, the size and thickness of each component shown in the drawing are arbitrarily shown for better understanding and ease of description, so the present disclosure is not necessarily limited to what is shown. In the drawings, the thickness of layers, films, panels, regions, etc., are exaggerated for clarity. And, in the drawings, for the convenience of explanation, the thickness of some layers and regions is exaggerated.

Additionally, when a part of a layer, film, region, substrate, etc. is referred to be “above” or “on” another part, this may include not only cases where it is “directly on” another part, but also cases where there are intervening elements in between. In contrast, when an element is referred to as being “directly on” another element, there are no intervening elements present. In addition, being “above” or “on” a reference part means being positioned above or below the reference part, and does not necessarily mean being positioned “above” or “on” it in the opposite direction of gravity.

In addition, throughout the specification, when a part is referred to “include” a certain component, this means that it may further include other components rather than excluding other components, unless specifically stated to the contrary.

In addition, throughout the specification, when it comes to “on a plane,” it means when the target part is viewed from above, and when it comes to “cross-section,” it means when the cross-section of the target part is vertically cut from the side.

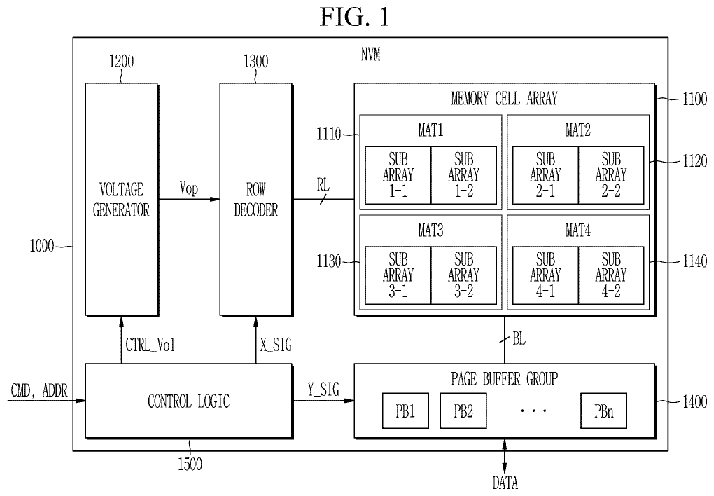

FIG. 1 is a diagram illustrating a non-volatile memory device according to some implementations.

Referring to FIG. 1, a non-volatile memory device 1000 may include a memory cell array 1100, a voltage generator 1200, a row decoder 1300, a page buffer group 1400, and a control logic 1500.

In some implementations, the memory cell array 1100 may be coupled to the row decoder 1300 through the row lines RL. The memory cell array 1100 may be coupled to the page buffer group 1400 through bit lines BLs.

In some implementations, the memory cell array 1100 may include a plurality of mats. According to some implementations, the memory cell array 1100 may include first to fourth mats 1110 to 1140. Each of a plurality of mats may include a plurality of sub arrays. In some implementations, the first mat 1110 may include a 1-1 sub array SUB ARRAY1-1 and a 1-2 sub array SUB ARRAY1-2. In some implementations, the second mat 1120 may include a 2-1 sub array SUB ARRAY2-1 and a 2-2 sub array SUB ARRAY2-2. In some implementations, the third mat 1130 may include a 3-1 sub array SUB ARRAY3-1 and a 3-2 sub array SUB ARRAY3-2. In some implementations, the fourth mat 1140 may include a 4-1 sub array SUB ARRAY4-1 and a 4-2 sub array SUB ARRAY4-2.

In some implementations, a plurality of sub arrays may include a plurality of memory blocks. Each of the plurality of memory blocks may include a plurality of memory cells. In some implementations, a plurality of memory cells may be non-volatile memory cells.

Each of the plurality of memory cells may be composed of a single level cell SLC that stores one bit of data, a multi-level cell MLC that stores two bits of data, a triple level cell TLC that stores three bits of data, a quad level cell QLC that can store four bits of data, or may store five or more bits of data.

The voltage generator 1200 may generate the operating voltages Vop using an external power voltage supplied to the non-volatile memory device 1000. The voltage generator 1200 may operate in response to the control of the control logic 1500.

In some implementations, the voltage generator 1200 may generate operating voltages Vop used in a program operation, a read operation, and an erase operation. For example, the voltage generator 1200 may generate a program voltage, a pass voltage, a read voltage, and an erase voltage. The operating voltages Vop may be supplied to the memory cell array 1100 by the row decoder 1300.

The row decoder 1300 may be coupled to the memory cell array 1100 through the row lines RL. The row lines RL may include string selection lines, word lines, and ground selection lines.

The row decoder 1300 may be configured to operate in response to the control of control logic 1500. The row decoder 1300 may receive a row signal X_SIG from the control logic 1500. In some implementations, the row decoder 1300 may select at least one word line of a plurality of word lines based on the row signal X_SIG and apply the operating voltages Vop provided from the voltage generator 1200 to at least one word line.

In some implementations, during a program operation, the row decoder 1300 may apply a program voltage to the selected word line among a plurality of word lines and apply a pass voltage having a lower level than the program voltage to unselected word lines. During the program verification operation, the row decoder 1300 may apply a verification voltage to the selected word line and apply a verification pass voltage having a higher level than the verification voltage to the unselected word lines.

During a read operation, the row decoder 1300 may apply a read voltage to the selected word line and apply a read pass voltage having a higher level than the read voltage to the unselected word lines.

A page buffer group 1400 may include a plurality of page buffers PB1 to PBn. A plurality of page buffers PB1 to PBn may be coupled to the memory cell array 1100 through bit lines BLs. A plurality of page buffers PB1 to PBn may operate in response to the control of a control logic 1500.

In some implementations, a plurality of page buffers PB1 to PBn may receive data DATA from the outside. A plurality of page buffers PB1 to PBn may select at least one bit line among the bit lines BL based on the column signal Y_SIG received from the control logic 1500.

In some implementations, during a program operation, a plurality of page buffers PB1 to PBn may transmit data received from the outside to the memory cells of the memory cell array 1100 through the bit lines BL. The memory cells may be programmed according to the received data. During a program verification operation, a plurality of page buffers PB1 to PBn may sense data stored in memory cells through bit lines BL.

During a read operation, the plurality of page buffers PB1 to PBn may sense data stored in memory cells through the first to fourth bit lines BL1 to BL4 and store the sensed data in a plurality of page buffers PB1 to PBn. In some implementations, a plurality of page buffers PB1 to PBn may sense the data stored in the memory cell array 1100 in response to a read command.

The control logic 1500 may be connected to the voltage generator 1200, the row decoder 1300, and the page buffer group 1400. The control logic 1500 may be configured to control overall operations of the non-volatile memory device 1000. The control logic 1500 may operate in response to a command CMD transmitted from the outside. The control logic 1500 may control the voltage generator 1200, the row decoder 1300, and the page buffer group 1400 by generating various signals in response to the command CMD and the address ADDR.

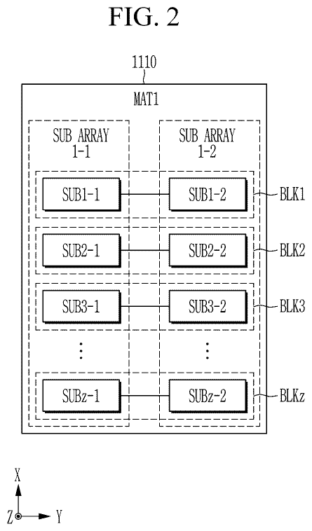

FIG. 2 is a diagram illustrating a plurality of sub arrays including a plurality of memory blocks according to some implementations.

Referring to FIG. 2, the first mat 1110 may include a 1-1 sub array SUB ARRAY1-1 and a 1-2 sub array SUB ARRAY1-2. The 1-1 sub array SUB ARRAY1-1 and the 1-2 sub array SUB ARRAY1-2 may include a plurality of memory blocks BLK1 to BLKz. In some implementations, the 1-1 sub array SUB ARRAY1-1 and the 1-2 sub array SUB ARRAY1-2 may be spaced apart by a specific distance along the Y direction.

In some implementations, each of the plurality of memory blocks BLK1 to BLKz may include a plurality of sub blocks. In some implementations, the first memory block BLK1 may include a 1-1 sub block SUB1-1 and a 1-2 sub block SUB1-2.

In some implementations, the 1-1 sub array SUB ARRAY1-1 may include one sub block included in each of the plurality of memory blocks BLK1 to BLKz. According to some implementations, the 1-1 sub array SUB ARRAY1-1 may include the 1-1 sub block SUB1-1 included in the first memory block BLK1. According to some implementations, the 1-1 sub array SUB ARRAY1-1 may include the 2-1 sub block SUB2-1 included in the second memory block BLK2.

In some implementations, the 1-2 sub array SUB ARRAY1-2 may include another sub block included in each of the plurality of memory blocks. In some implementations, the 1-2 sub array SUB ARRAY1-2 may include a 1-2 sub block SUB1-2 included in the first memory block BLK1. In some implementations, the 1-2 sub array SUB ARRAY1-2 may include a 2-2 sub block SUB2-12 included in the second memory block BLK2.

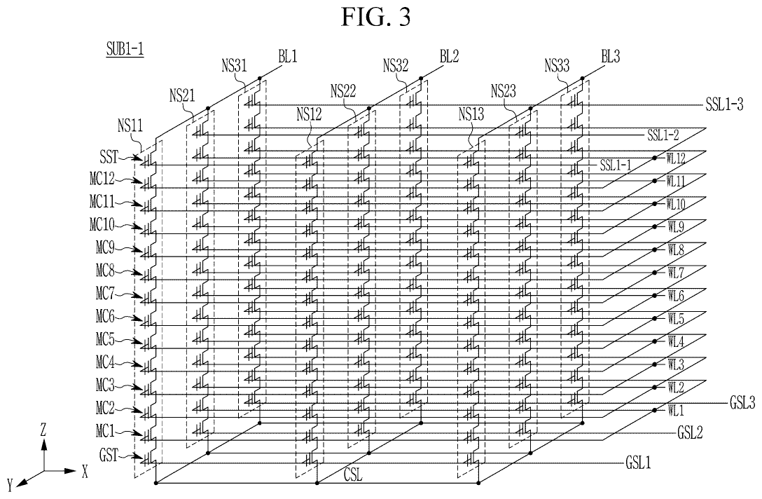

FIG. 3 is a circuit diagram illustrating a sub block according to some implementations.

Referring to FIG. 3, the 1-1 sub block SUB1-1 may include a plurality of memory cell strings NS11 to NS33 connected between the bit lines BL1, BL2, and BL3 and a common source line CSL. Each of the plurality of memory cell strings NS11 to NS33 may include a string selection transistor SST, a plurality of memory cells MC1 to MC12, and a ground selection transistor GST.

The string selection transistor SST may be connected to the string selection lines SSL1-1, SSL1-2, and SSL1-3. The plurality of memory cells MC1 to MC12 may be connected to a plurality of word lines WL1 to WL12 stacked on the substrate, respectively. The ground selection transistor GST may be connected to the ground selection lines GSL1, GSL2, and GSL3. The string selection transistor SST may be connected to the bit lines BL1, BL2, and BL3, and the ground selection transistor GST may be connected to the common source line CSL. The word line (e.g., WL1) having the same height in the Z-axis direction may be connected in common to a plurality of memory cell strings NS11 to NS33, and the ground selection lines GSL1, GSL2, and GSL3 and the string selection lines SSL1-1, SSL1-2, and SSL1-3 may be separated from each other and connected to a plurality of memory cell strings NS11 to NS33.

In some implementations, structures of the 1-1 to z-1 sub blocks (SUB1-1 to SUBz-1) included in the 1-1 sub array SUB ARRAY1-1 of FIG. 2 and the 1-2 to z-2 sub blocks (SUB1-2 to SUBz-2) included in the 1-2 sub array SUB ARRAY1-2 may be the same as those of the 1-1 sub block SUB1-1 described with reference to FIG. 3.

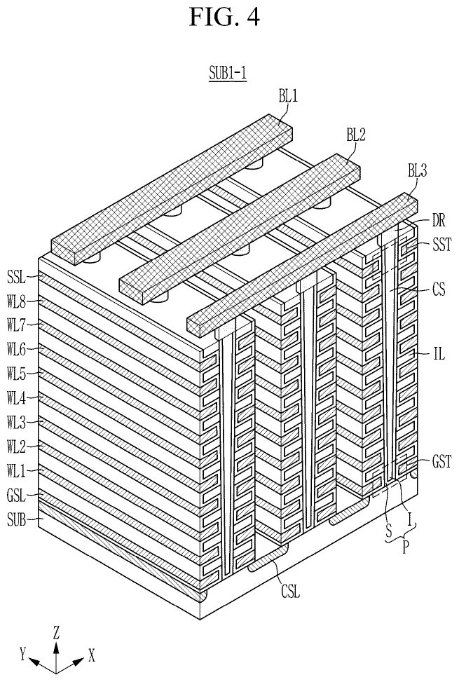

FIG. 4 is a perspective view illustrating a sub block according to some implementations.

Referring to FIG. 4, the 1-1 sub block SUB1-1 may be positioned on a substrate SUB. In some implementations, the substrate SUB has a first conductivity type (e.g., a p-type) and may extend in the X direction. In some implementations, the substrate SUB may include a common source line CSL doped with impurities of a second conductivity type (e.g., n-type). In some implementations, the substrate SUB may be implemented with polysilicon, and a plate type common source line CSL may be disposed on the substrate SUB. A plurality of insulation layers IL extending along the Y direction are sequentially provided on the substrate SUB along the Z direction, and a plurality of insulation layer layers ILs may be spaced apart by a specific distance along the Z direction. In some implementations, the plurality of insulation layers ILs may include an insulation material such as silicon oxide.

In some implementations, a plurality of pillars P are sequentially disposed on the substrate SUB in the X direction and may penetrate a plurality of insulation layers IL in the Z direction. In some implementations, a plurality of pillars P may penetrate a plurality of insulation layers IL to be in contact with the substrate SUB. Specifically, the surface layer S of each of the plurality of pillars P may include a silicon material having a first type and may function as a channel region. In some implementations, each of the plurality of pillars P may be referred to as a channel structure or a vertical channel structure. Meanwhile, the inner layer I of each of the plurality of pillars P may include an insulation material such as silicon oxide or an air gap.

In some implementations, the charge storage layer CS is provided along the exposed surfaces of the plurality of insulation layers ILs, the plurality of pillars P, and the substrate SUB. The charge storage layer CS may include a gate insulation layer (or tunneling insulation layer), a charge trap layer, and a blocking insulation layer. In some implementations, the charge storage layer CS may have an oxide-nitride-oxide ONO structure. In some implementations, a gate electrode GE such as the ground selection line GSL string selection line SSL and the word lines WL1 to WL8 may be provided on the exposed surface of the charge storage layer CS.

In some implementations, drain contacts or drains DR may be provided on each of the plurality of pillars P. In some implementations, the drains DR may include a silicon material doped with impurities having a second conductivity type. In some implementations, the bit lines BL1 to BL3 may extend in the X direction and may be spaced apart from each other by a specific distance along the Y direction on the drains DR.

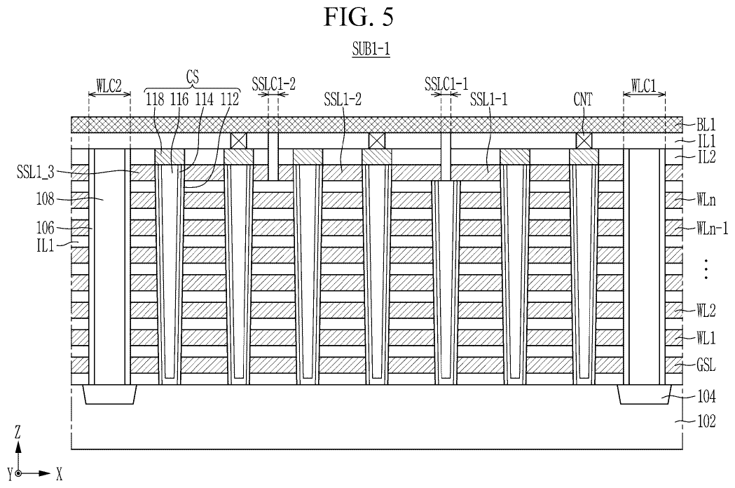

FIG. 5 is a cross-sectional view illustrating a sub block according to some implementations.

Referring to FIG. 5, the 1-1 sub block SUB1-1 may be located on the substrate 102.

In some implementations, the substrate 102 may have a main surface extending in an X direction and a Y direction. The common source regions 104 may extend in the Y direction in the substrate 102. The common source regions 104 may function as source regions that supply current to memory cells. In some implementations, the common source regions 104 may be impurity regions doped with n-type impurities at a high concentration or polysilicon regions.

In some implementations, the first word line cut WLC1 and the second word line cut WLC2 may extend in the Y direction parallel to the main surface of the substrate 102. The first word line cut WLC1 and the second word line cut WLC2 may limit the width of each of the plurality of word lines WL1 to WLn in the X direction. In some implementations, the plurality of word lines WL1 to WLn may be repeatedly disposed to be spaced apart from each other at regular intervals by the first word line cut WLC1 and the second word line cut WLC2.

In some implementations, an insulation spacer 106 and a common source line 108 may be formed inside each of the first word line cut WLC1 and the second word line cut WLC2. Each common source line 108 may extend along the Y direction on the corresponding common source region 104. In some implementations, each of the first word line cut WLC1 and the second word line cut WLC2 may be formed of an insulation structure.

In some implementations, a ground selection line GSL and a plurality of word lines WL1 to WLn may be sequentially stacked between the first word line cut WLC1 and the second word line cut WLC2. The plurality of word lines WL1 to WLn may extend on the substrate 102 in a direction parallel to the main surface and may be spaced apart from each other in a Z direction perpendicular to the main surface of the substrate 102 to overlap each other. In some implementations, a plurality of word lines WL1 to WLn may be stacked on the substrate 102 in the Z direction.

In some implementations, a 1-1 string selection line SSL1-1, a 1-2 string selection line SSL1-2, and a 1-3 string selection line SSL1-3 may be disposed on a plurality of word lines WL1 to WLn.

In some implementations, the 1-1 string selection line SSL1-1, the 1-2 string selection line SSL1-2, and the 1-3 string selection line SSL1-3 may be separated from each other by the 1-1 string selection line cut SSLC1-1 and the 1-2 string selection line cut SSLC1-2 and may be separated from each other. In some implementations, the 1-1 string selection line cut SSLC1-1 and the 1-2 string selection line cut SSLC1-2 may be filled with an insulation layer.

In some implementations, the ground selection line GSL, the plurality of word lines WL1 to WLn, the 1-1 string selection line SSL1-1, the 1-2 string selection line SSL1-2, and the 1-3 string selection line SSL1-3 may be formed of a metal, a metal silicide, an impurity-doped semiconductor, or a combination thereof.

In some implementations, an insulation layer IL1 may be disposed between the substrate 102 and the ground selection line GSL, and between each of the ground selection lines GSL, the plurality of word lines WL1 to WLn, the 1-1 string selection line SSL1-1, the 1-2 string selection line SSL1-2, and the 1-3 string selection line SSL1-3. The insulation layer IL1 may be formed of silicon oxide, silicon nitride, or silicon oxynitride.

In some implementations, a plurality of channel structures CSs may extend in the Z direction through a ground selection line GSL, a plurality of word lines WL1 to WLn, a 1-1 string selection line SSL1-1, a 1-2 string selection line SSL1-2, a 1-3 string selection line SSL1-3, and a plurality of insulation layers IL1. A plurality of channel structures CS may be disposed to be spaced apart from each other with a specific interval therebetween in the X direction and the Y direction.

In some implementations, a plurality of channel structures CS may include a gate dielectric layer 112, a channel region 114, a buried insulation layer 116, and a drain region 118, respectively.

In some implementations, the inner space of the channel region 114 may be filled with a buried insulation layer 116. The buried insulation layer 116 may be made of an insulating material. The drain region 118 may be formed of a polysilicon layer doped with impurities. A plurality of drain regions 118 may be insulated from each other by an insulation layer IL2. The insulation layer IL2 may be formed of an oxide layer, a nitride layer, or a combination thereof. Each drain region 118 may be connected to a corresponding first bit line BL1 among a plurality of bit lines through a plurality of contacts CNTs. A plurality of contacts CNTs may be insulated from each other by an insulation layer IL1.

In some implementations, in the manufacturing process of the non-volatile memory device 1000, a plurality of insulation layers IL1 and a plurality of sacrificial insulation layers (not shown) may be alternately stacked one by one on the substrate 102. For example, a plurality of insulation layers IL1 may be made of a silicon oxide layer, and a plurality of sacrificial insulation layers may be made of a silicon nitride layer. In this case, a plurality of sacrificial insulation layer layers may serve to secure a space for forming a plurality of gate lines including a ground selection line GSL, a plurality of word lines WL1 to WLn 1-1 string selection line SSL1-1, a 1-2 string selection line SSL1-2, and a 1-3 string selection line SSL1-3 in a subsequent process. Subsequently, a plurality of channel structures CS penetrating a plurality of insulation layers IL1 and a plurality of sacrificial insulation layers may be formed. Next, a plurality of sacrificial insulation layers may be replaced with a plurality of gate lines through word line cut holes corresponding to the first word line cut WLC1 and the second word line cut WLC2, respectively. The word line cut holes may be filled with an insulation spacer 106 and a common source line 108.

In some implementations, the thickness of each of the plurality of gate lines substituted from the plurality of sacrificial insulation layers in the Z direction may vary depending on the distance from the adjacent word line cut among the first word line cut WLC1 and the second word line cut WLC2. In some implementations, in gate lines arranged at the same level, the thickness of the region relatively close to the adjacent word line cut among the first word line cut WLC1 and the second word line cut WLC2 may be thicker in the Z direction than a region where the distance to an adjacent word line cut among the first word line cut WLC1 and the second word line cut WLC2 is relatively farther.

In some implementations, a thickness in the Z direction of a word line connected to internal memory cells formed in internal channel structures, which are relatively far from the adjacent word line cut among the first word line cut WLC1 and the second word line cut WLC2, may be thinner than the thickness in the Z direction of the word lines connected to the external memory cells formed in the external channel structures where the distance to an adjacent word line cut among the first word line cut WLC1 and the second word line cut WLC2 is relatively close. Accordingly, the data stored in the internal memory cells formed in the internal channel structures may have a higher rate of error bit occurrence compared to the data stored in the external memory cells formed in the external channel structures.

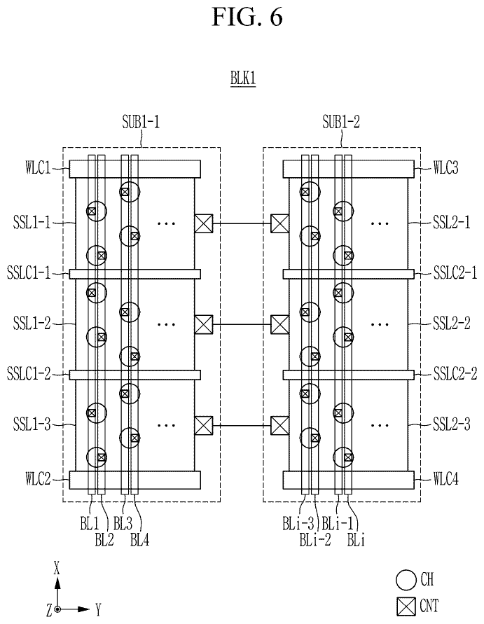

FIG. 6 is a plan view illustrating a memory block according to some implementations.

Referring to FIG. 6, the first memory block BLK1 may include a 1-1 sub block SUB1-1 and a 1-2 sub block SUB1-2. The 1-1 sub block SUB1-1 may be included in the 1-1 sub array SUB ARRAY1-1, and the 1-2 sub block SUB1-2 may be included in the 1-2 sub array SUB ARRAY1-2.

In some implementations, the 1-1 sub block SUB1-1 may include a first word line cut WLC1, a second word line cut WLC2, a 1-1 string selection line cut SSLC1-1, a 1-2 string selection line cut SSLC1-2, a 1-1 string selection line SSL1-1, a 1-2 string selection line SSL1-2, and a 1-3 string selection line SSL1-3.

In some implementations, the 1-1 string selection line cut SSLC1-1 and the 1-2 string selection line cut SSLC1-2 may be positioned between the first word line cut WLC1 and the second word line cut WLC2. The 1-1 string selection line cut SSLC1-1 and the 1-2 string selection line cut SSLC1-2 may be spaced apart from each other in the X direction and may extend in the Y direction.

In some implementations, the 1-1 string selection line SSL1-1 may be positioned between the first word line cut WLC1 and the 1-1 string selection line cut SSLC1-1. The 1-2 string selection line SSL1-2 may be positioned between the 1-1 string selection line cut SSLC1-1 and the 1-2 string selection line cut SSLC1-2. The 1-3 string selection line SSL1-3 may be positioned between the 1-2 string selection line cut SSLC1-2 and the second word line cut WLC2.

In some implementations, the 1-2 sub block SUB1-2 may include a third word line cut WLC3, a fourth word line cut WLC4, a 2-1 string selection line cut SSLC2-1, a 2-2 string selection line cut SSLC2-2, a 2-1 string selection line SSL2-1, a 2-2 string selection line SSL2-2, and a 2-3 string selection line SSL2-3.

In some implementations, the 2-1 string selection line cut SSLC2-1 and the 2-2 string selection line cut SSLC2-12 may be positioned between the third word line cut WLC3 and the fourth word line cut WLC4.

In some implementations, the 2-1 string selection line SSL2-1 may be positioned between the third word line cut WLC3 and the 2-1 string selection line cut SSLC2-1. The 2-2 string selection line SSL2-12 may be positioned between the 2-1 string selection line cut SSLC2-1 and the 2-2 string selection line cut SSLC2-2. The 2-3 string selection line SSL2-3 may be positioned between the 2-2 string selection line cut SSLC2-12 and the fourth word line cut WLC4.

In some implementations, the 1-1 sub block SUB1-1 and the 1-2 sub block SUB1-2 may include a plurality of channel holes CH and a plurality of bit lines BL1 to BLi. In some implementations, a plurality of channel holes CH may correspond to a plurality of channel structures CS of FIG. 5. One of the plurality of channel holes CH may be connected to one of the plurality of bit lines BL1 to BLi through a contact CNT.

In some implementations, the 1-1 string selection line SSL1-1 may be connected to the 2-1 string selection line SSL2-1 through a contact CNT. The 1-2 string selection line SSL1-2 may be connected to the 2-2 string selection line SSL2-12 through a contact CNT. The 1-3 string selection line SSL1-3 may be connected to the 2-3 string selection line SSL2-3 through a contact CNT.

In some implementations, memory cells formed in the channel holes positioned between the first word line cut WLC1 and the 1-1 string selection line cut SSLC1-1 may be connected to the 1-1 string selection line SSL1-1. In some implementations, memory cells formed in the channel holes positioned between the third word line cut WLC3 and the 2-1 string selection line cut SSLC2-1 may be connected to the 2-1 string selection line SSL2-1.

In some implementations, memory cells formed in the channel holes positioned between the 1-1 string selection line cut SSLC1-1 and the 1-2 string selection line cut SSLC1-2 may be connected to the 1-2 string selection line SSL1-2. In some implementations, memory cells formed in the channel holes positioned between the 2-1 string selection line cut SSLC2-1 and the 2-2 string selection line cut SSLC2-12 may be connected to the 2-2 string selection line SSL2-2.

In some implementations, memory cells formed in the channel holes positioned between the 1-2 string selection line cut SSLC1-2 and the second word line cut WLC2 may be connected to the 1-3 string selection line SSL1-3. In some implementations, memory cells formed in the channel holes positioned between the 2-2 string selection line cut SSLC2-12 and the fourth word line cut WLC4 may be connected to the 2-3 string selection line SSL2-3.

In some implementations, the memory cells connected to the 1-2 string selection line SSL1-2 and the 2-2 string selection line SSL2-12 may be farther from the first word line cut WLC1 or the third word line cut WLC3 than the memory cells connected to the 1-1 string selection line SSL1-1 and the 2-1 string selection line SSL2-1. Data stored in memory cells connected to the 1-2 string selection line SSL1-2 and the 2-2 string selection line SSL2-2, in which the distance from the first word line cut WLC1 or the third word line cut WLC3 is farther than memory cells connected to the 1-1 string selection line SSL1-1 and the 2-1 string selection line SSL2-1, may have a greater degree of occurrence of error bits than data stored in memory cells connected to the 1-1 string selection line SSL1-1 and the 2-1 string selection line SSL2-1.

In some implementations, the memory cells connected to the 1-2 string selection line SSL1-2 and the 2-2 string selection line SSL2-12 may be farther from the second word line cut WLC2 or the fourth word line cut WLC4 than the memory cells connected to the 1-3 string selection line SSL1-3 and the 2-3 string selection line SSL2-3. Data stored in memory cells connected to the 1-2 string selection line SSL1-2 and the 2-2 string selection line SSL2-2, in which the distance from the second word line cut WLC2 or the fourth word line cut WLC4 is farther than memory cells connected to the 1-3 string selection line SSL1-3 and the 2-3 string selection line SSL2-3, may have a greater degree of occurrence of error bits than data stored in memory cells connected to the 1-3 string selection line SSL1-3 and the 2-3 string selection line SSL2-3.

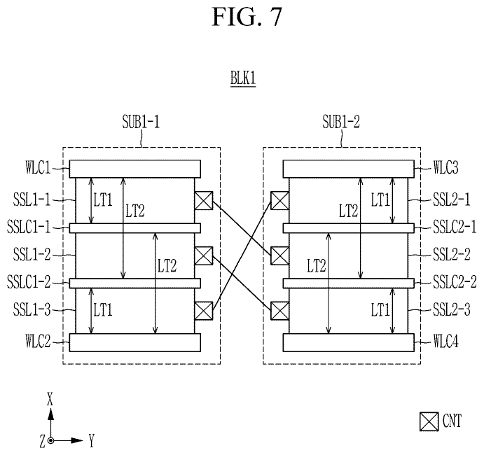

FIG. 7 is a drawing for explaining the connection relationship among three string selection lines included in each of a plurality of sub blocks according to some implementations.

Referring to FIG. 7, the 1-1 sub block SUB1-1 may include a first word line cut WLC1, a second word line cut WLC2, a 1-1 string selection line cut SSLC1-1, a 1-2 string selection line cut SSLC1-2, a 1-1 string selection line SSL1-1, a 1-2 string selection line SSL1-2, and a 1-3 string selection line SSL1-3.

In some implementations, the distance between the first word line cut WLC1 and the 1-1 string selection line cut SSLC1-1 may correspond to the first length LT1. The distance between the 1-1 string selection line cut SSLC1-1 and the second word line cut WLC2 may correspond to the second length LT2 farther than the first length LT1. The distance between the first word line cut WLC1 and the 1-2 string selection line cut SSLC1-2 may correspond to the second length LT2. The distance between the 1-2 string selection line cut SSLC1-2 and the second word line cut WLC2 may correspond to the first length LT1.

In some implementations, the 1-2 sub block SUB1-2 may include a third word line cut WLC3, a fourth word line cut WLC4, a 2-1 string selection line cut SSLC2-1, a 2-2 string selection line cut SSLC2-2, a 2-1 string selection line SSL2-1, a 2-2 string selection line SSL2-2, and a 2-3 string selection line SSL2-3.

In some implementations, a distance between the third word line cut WLC3 and the 2-1 string selection line cut SSLC2-1 may correspond to the first length LT1. The distance between the 2-1 string selection line cut SSLC2-1 and the fourth word line cut WLC4 may correspond to the second length LT2 farther than the first length LT1. The distance between the third word line cut WLC3 and the 2-2 string selection line cut SSLC2-12 may correspond to the second length LT2. The distance between the 2-2 string selection line cut SSLC2-12 and the fourth word line cut WLC4 may correspond to the first length LT1.

In some implementations, the 1-1 string selection line SSL1-1 may have a distance from the first word line cut WLC1 located between the 1-1 string selection line cut SSLC1-1 corresponding to the first length LT1. In some implementations, a 1-1 string selection line SSL1-1 may be connected to a 2-2 string selection line SSL2-12 located between a 2-1 string selection line cut SSLC2-1 whose distance from a third word line cut WLC3 corresponds to a first length LT1 and a 2-2 string selection line cut SSLC2-12 whose distance from a third word line cut WLC3 corresponds to a second length LT2 farther than the first length LT1 through a contact CNT.

In some implementations, the 1-2 string selection line SSL1-2 may be located between the 1-1 string selection line cut SSLC1-1 and the 1-2 string selection line cut SSLC1-2 which is farther than the 1-1 string selection line cut SSLC1-1 from the first word line cut WLC1. The 1-2 string selection line SSL1-2 may be connected to the 2-3 string selection line SSL2-3 located between the 2-2 string selection line cut SSLC2-12 and the fourth word line cut WLC4 at a distance corresponding to the first length LT1 from the fourth word line cut WLC4 through a contact CNT.

In some implementations, the 1-3 string selection line SSL1-3 may be located between the 1-2 string selection line cut SSLC1-2, in which the distance from the second word line cut WLC2 corresponds to the first length LT1, and the second word line cut WLC2. The 1-3 string selection line SSL1-3 may be connected to the 2-1 string selection line SSL2-1 located between a 2-1 string selection line cut SSLC2-1 in which the distance from the third word line cut WLC3 corresponds to the first length LT1 and third word line cut WLC3 through a contact CNT.

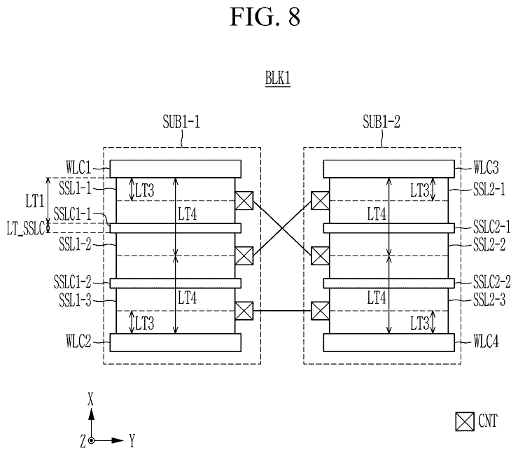

FIG. 8 is a drawing for explaining another example of a connection relationship between three string selection lines each included in a plurality of sub blocks according to some implementations.

Referring to FIG. 8, a string selection line of the 1-1 sub block SUB1-1, in which distance from adjacent word line cuts among the first word line cut WLC1 and the second word line cut WLC2 corresponds to a third length LT3, may be connected to a string selection line of a 1-2 sub block SUB1-2, in which distance from adjacent word line cuts among the third word line cut WLC3 and the fourth word line cut WLC4 corresponds to a fourth length LT4 farther than the third length LT3, through a contact CNT.

In some implementations, a word line cut adjacent to the 1-1 string selection line SSL1-1 among the first word line cut WLC1 and the second word line cut WLC2 may be a first word line cut WLC1. The distance between the 1-1 string selection line SSL1-1 and the first word line cut WLC1 may be a third length LT3.

In some implementations, a distance between the first word line cut WLC1 and the 1-2 string selection line SSL1-2 and a distance between the second word line cut WLC2 and the 1-2 string selection line SSL1-2 may be the same as the fourth length LT4.

In some implementations, a word line cut adjacent to the 1-3 string selection line SSL1-3 among the first word line cut WLC1 and the second word line cut WLC2 may be a second word line cut WLC2. The distance between the 1-3 string selection line SSL1-3 and the second word line cut WLC2 may be a third length LT3.

In some implementations, the 1-1 string selection line SSL1-1 whose distance to the first word line cut WLC1 corresponds to the third length LT3 may be connected to the 2-2 string selection line SSL2-12 whose distance to the third word line cut WLC3 or the fourth word line cut WLC4 corresponds to the fourth length LT4 through the contact CNT.

In some implementations, the string selection line of the 1-1 sub block SUB1-1 whose distance to the adjacent word line cut of the first word line cut WLC1 and the second word line cut WLC2 corresponds to the fourth length LT4 may be connected to the string selection line of the 1-2 sub block SUB1-2 whose distance to the adjacent word line cut of the third word line cut WLC3 and the fourth word line cut WLC4 corresponds to the third length LT3 through the contact CNT.

In some implementations, the 1-2 string selection line SSL1-2 whose distance to the first word line cut WLC1 or the second word line cut WLC2 corresponds to the fourth length LT4 may be connected to the 2-1 string selection line SSL2-1 whose distance to the third word line cut WLC3 corresponds to the third length LT3 through the contact CNT.

In some implementations, the string selection line of the 1-1 sub block SUB1-1 whose distance to the adjacent word line cut of the first word line cut WLC1 and the second word line cut WLC2 corresponds to the third length LT3 may be connected to the string selection line of the 1-2 sub block SUB1-2 whose distance to the adjacent word line cut of the third word line cut WLC3 and the fourth word line cut WLC4 corresponds to the fourth length LT4 through the contact CNT.

In some implementations, the 1-3 string selection line SSL1-3 whose distance to the second word line cut WLC2 corresponds to the third length LT3 may be connected to the 2-3 string selection line SSL2-3 whose distance to the fourth word line cut WLC4 corresponds to the third length LT3 through the contact CNT.

In some implementations, when the number of string selection lines included in each of the 1-1 sub block SUB1-1 and the 1-2 sub block SUB1-2 is odd, the sum of the length corresponding to the distance between the one string selection line and the word line cut of the 1-1 sub block SUB1-1 and the length corresponding to the distance between the word line cut and the other string selection line of the 1-2 sub block SUB1-2 connected to the one string selection line of the 1-1 sub block SUB1-1 may be equal to the sum of the length corresponding to the distance between the word line cut and the other string selection line of the 1-1 sub block SUB1-1 and the length corresponding to the distance between the word line cut and the other string selection line of the 1-2 sub block SUB1-2 connected to the other string selection line of the 1-1 sub block SUB1-1.

In some implementations, a sum of a third length LT3 corresponding to a distance between a 1-1 string selection line SSL1-1 and a first word line cut WLC1 and a fourth length LT4 corresponding to a distance between a 2-2 string selection line SSL2-12 connected to 1-1 string selection line SSL1-1 and a third word line cut WLC3 or a fourth word line cut WLC4 may be equal to a sum of a fourth length LT4 corresponding to a distance between a 1-2 string selection line SSL1-2 and a first word line cut WLC1 or a second word line cut WLC2, and a third length LT3 corresponding to a distance between a 2-1 string selection line SSL2-1 connected to the 1-2 string selection line SSL1-2 and a third word line cut WLC3.

In some implementations, when the number of string selection lines included in the 1-1 sub block SUB1-1 and the 1-2 sub block SUB1-2 is odd, the difference between the sum of the length corresponding to the distance between the one string selection line and the word line cut of the 1-1 sub block SUB1-1 and the length corresponding to the distance between the one string selection line and the word line cut of the 1-2 sub block SUB1-2 connected to the one string selection line of the 1-1 sub block SUB1-1 and the sum of the length corresponding to the distance between the word line cut and the other string selection line of the 1-1 sub block SUB1-1 and the length corresponding to the distance between the word line cut and the other string selection line of the 1-2 sub block SUB1-2 connected to the other string selection line of the 1-1 sub block SUB1-1 may correspond to the sum of the word line cut and the first length LT1 corresponding to the distance between the adjacent string selection line cut and the word line cut and the string selection line cut length LT_SSLC corresponding to the X direction length of the string selection line cut.

In some implementations, the difference between the sum of the third length LT3 corresponding to the distance between the first word line cut WLC1 and the 1-1 string selection line SSL1-1, and the fourth length LT4 corresponding to the distance between the 2-2 string selection line SSL2-12 connected to the 1-1 string selection line SSL1-1 and the third word line cut WLC3 or the fourth word line cut WLC4 and the sum of the third length LT3 corresponding to the distance between the 1-3 string selection line SSL1-3 and the second word line cut WLC2, and the third length LT3 corresponding to the distance between the 2-3 string selection line SSL2-3 and the fourth word line cut WLC4 connected to the 1-3 string selection line SSL1-3 may correspond to a difference between the fourth length LT4 and the third length LT3. The difference between the fourth length LT4 and the third length LT3 may correspond to the sum of the first length LT1 and the string selection line cut length LT_SSLC.

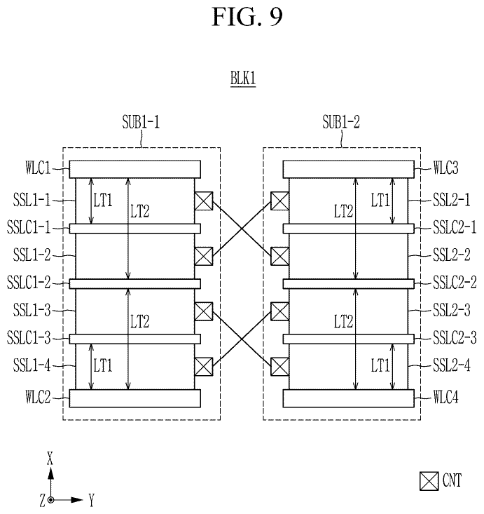

FIG. 9 is a drawing for explaining the connection relationship among four string selection lines included in each of a plurality of sub blocks according to some implementations.

Referring to FIG. 9, a 1-1 sub block SUB1-1 may include a first word line cut WLC1, a second word line cut WLC2, a 1-1 string selection line cut SSLC1-1, a 1-2 string selection line cut SSLC1-2, a 1-3 string selection line cut SSLC1-3, a 1-1 string selection line SSL1-1, a 1-2 string selection line SSL1-2, a 1-3 string selection line SSL1-3, and a 1-4 string selection line SSL1-4.

In some implementations, the distance between the 1-1 string selection line cut SSLC1-1 and the first word line cut WLC1 may correspond to the first length LT1. The distance between the 1-2 string selection line cut SSLC1-2 and the first word line cut WLC1 or the second word line cut WLC2 may correspond to the second length LT2 farther than the first length LT1. The distance between the 1-3 string selection line cut SSLC1-3 and the second word line cut WLC2 may correspond to the first length LT1.

In some implementations, the 1-2 sub block SUB1-2 may include a third word line cut WLC3, a fourth word line cut WLC4, a 2-1 string selection line cut SSLC2-1, a 2-2 string selection line cut SSLC2-2, a 2-3 string selection line cut SSLC2-3, a 2-1 string selection line SSL2-1, a 2-2 string selection line SSL2-2, a 2-3 string selection line SSL2-3, and a 2-4 string selection line SSL2-4.

In some implementations, a distance between the 2-1 string selection line cut SSLC2-1 and the third word line cut WLC3 may correspond to the first length LT1. The distance between the 2-2 string selection line cut SSLC2-12 and the third word line cut WLC3 or the fourth word line cut WLC4 may correspond to the second length LT2. The distance between the 2-3 string selection line cut SSLC2-3 and the fourth word line cut WLC4 may correspond to the first length LT1.

In some implementations, the 1-1 string selection line SSL1-1 may be positioned between the 1-1 string selection line cut SSLC1-1 whose distance from the first word line cut WLC1 corresponds to the first length LT1 and the first word line cut WLC1. The 1-1 string selection line SSL1-1 may be connected to the 2-2 string selection line SSL2-12 positioned between a 2-1 string selection line cut SSLC2-1 whose distance from the third word line cut WLC3 corresponds to the first length LT1 and a 2-2 string selection line cut SSLC2-12 whose distance from the third word line cut WLC3 corresponds to the second length LT2 through the contact CNT.

In some implementations, the 1-2 string selection line SSL1-2 may be positioned between the 1-2 string selection line cut SSLC1-2 whose distance from the first word line cut WLC1 or the second word line cut WLC2 corresponds to the second length LT2 and the 1-1 string selection line cut SSLC1-1. The 1-2 string selection line SSL1-2 may be connected via a contact CNT to a 2-1 string selection line SSL2-1 located between the 2-1 string selection line cut SSLC2-1 whose distance from the third word line cut WLC3 corresponds to the first length LT1 and the third word line cut WLC3.

In some implementations, the 1-3 string selection line SSL1-3 may be positioned between the 1-3 string selection line cut SSLC1-3 whose distance from the second word line cut WLC2 corresponds to the first length LT1 and the 1-2 string selection line cut SSLC1-2. The 1-3 string selection line SSL1-3 may be connected via contact CNT to a 2-4 string selection line SSL2-4 located between the 2-3 string selection line cut SSLC2-3 whose distance from the fourth word line cut WLC4 corresponds to the first length LT1 and the fourth word line cut WLC4.

In some implementations, the 1-4 string selection line SSL1-4 may be positioned between the 1-3 string selection line cut SSLC1-3 and the fourth word line cut WLC4. The 1-4 string selection line SSL1-4 may be connected to the 2-3 string selection line SSL2-3 positioned between the 2-2 string selection line cut SSLC2-12 and the 2-3 string selection line cut SSLC2-3 through a contact CNT.

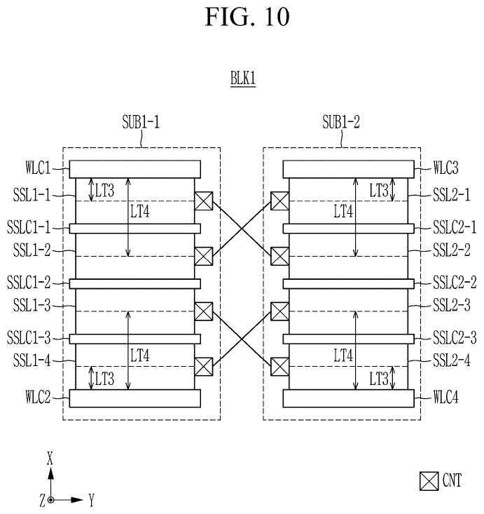

FIG. 10 is a drawing for explaining another example of a connection relationship among four string selection lines each included in a plurality of sub blocks according to some implementations.

Referring to FIG. 10, a string selection line of the 1-1 sub block SUB1-1 whose distance from adjacent word line cuts among the first word line cut WLC1 and the second word line cut WLC2 corresponds to a third length LT3 may be connected to a string selection line of a 1-2 sub block SUB1-2 whose distance from adjacent word line cuts among the third word line cut WLC3 and the fourth word line cut WLC4 corresponds to a fourth length LT4 farther than the third length LT3 through a contact CNT.

In some implementations, the 1-1 string selection line SSL1-1 whose distance to the first word line cut WLC1 corresponds to the third length LT3 may be connected to the 2-2 string selection line SSL2-12 whose distance to the third word line cut WLC3 corresponds to the fourth length LT4 through the contact CNT.

In some implementations, the 1-4 string selection line SSL1-4 whose distance to the second word line cut WLC2 corresponds to the third length LT3 may be connected to the 2-3 string selection line SSL2-3 whose distance to the fourth word line cut WLC4 corresponds to the fourth length LT4 through the contact CNT.

In some implementations, the string selection line of the 1-1 sub block SUB1-1, in which the distance to the adjacent word line cut among the first word line cut WLC1 and the second word line cut WLC2 corresponds to the fourth length LT4 may be connected to the string selection line of a 1-2 sub block SUB1-2 whose distance from an adjacent word line cut among the third word line cut WLC3 and the fourth word line cut WLC4 corresponds to a third length LT3 closer than the fourth length LT4, through the contact CNT.

In some implementations, the 1-2 string selection line SSL1-2 whose distance to the first word line cut WLC1 corresponds to the fourth length LT4 may be connected to the 2-1 string selection line SSL2-1 whose distance to the second word line cut WLC2 corresponds to the third length LT3 through the contact CNT.

In some implementations, the 1-3 string selection line SSL1-3 whose distance to the second word line cut WLC2 corresponds to the fourth length LT4 may be connected to the 2-4 string selection line SSL2-4 whose distance to the fourth word line cut WLC4 corresponds to the third length LT3 through the contact CNT.

In some implementations, when the number of string selection lines included in each of the 1-1 sub block SUB1-1 and the 1-2 sub block SUB1-2 is even number, the sum of the length corresponding to the distance between the one string selection line and the word line cut of the 1-1 sub block SUB1-1 and the length corresponding to the distance between the word line cut and the other string selection line of the 1-2 sub block SUB1-2 connected to the one string selection line of the 1-1 sub block SUB1-1 may be equal to the sum of the length corresponding to the distance between the word line cut and the other string selection line of the 1-1 sub block SUB1-1 and the length corresponding to the distance between the word line cut and the other string selection line of the 1-2 sub block SUB1-2 connected to the other string selection line of the 1-1 sub block SUB1-1.

In some implementations, the sum of the third length LT3 corresponding to the distance between the 1-1 string selection line SSL1-1 and the first word line cut WLC1 and the fourth length LT4 corresponding to the distance between the 2-2 string selection line SSL2-12 and the third word line cut WLC3 connected to the 1-1 string selection line SSL1-1 may be the same as the sum of the fourth length LT4 corresponding to the distance between the 1-3 string selection line SSL1-3 and the second word line cut WLC2 and the third length LT3 corresponding to the distance between the 2-4 string selection line SSL2-4 and the fourth word line cut WLC4 connected to the 1-3 string selection line SSL1-3.

In some implementations, the sum of the fourth length LT4 corresponding to the distance between the 1-2 string selection line SSL1-2 and the first word line cut WLC1 and the third length LT3 corresponding to the distance between the 2-1 string selection line SSL2-1 and the third word line cut WLC3 connected to the 1-2 string selection line SSL1-2 may be the same as the sum of the third length LT3 corresponding to the distance between the 1-4 string selection line SSL1-4 and the second word line cut WLC2 and the fourth length LT4 corresponding to the distance between the 2-3 string selection line SSL2-3 and the fourth word line cut WLC4 connected to the 1-4 string selection line SSL1-4.

In some implementations, when one string selection line of the 1-1 sub block SUB1-1 and one string selection line of the 1-2 sub block SUB1-2 having different distances from the word line cut are connected, data stored in memory cells connected to one string selection line of the 1-1 sub block SUB1-1 and one string selection line of the 1-2 sub block SUB1-2 may have uniformity in the degree to which error bits are generated.

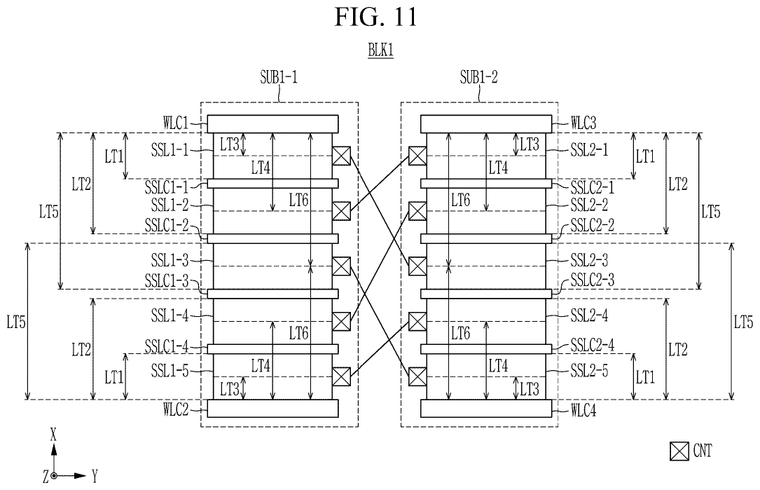

FIG. 11 is a drawing for explaining the connection relationship among five string selection lines included in each of a plurality of sub blocks according to some implementations.

Referring to FIG. 11, the 1-1 sub block SUB1-1 may include a first word line cut WLC1, a second word line cut WLC2, a 1-1 string selection line cut SSLC1-1, a 1-2 string selection line cut SSLC1-2, a 1-3 string selection line cut SSLC1-3, a 1-4 string selection line cut SSLC1-4, a 1-1 string selection line SSL1-1, a 1-2 string selection line SSL1-2, a 1-3 string selection line SSL1-3, a 1-4 string selection line SSL1-4, and a 1-5 string selection line SSL1-5.

In some implementations, the distance between the 1-1 string selection line cut SSLC1-1 and the first word line cut WLC1 may correspond to the first length LT1. The distance between the 1-2 string selection line cut SSLC1-2 and the first word line cut WLC1 may correspond to the second length LT2. In some implementations, a distance between the 1-2 string selection line cut SSLC1-2 and the second word line cut WLC2 may correspond to a fifth length LT5 farther than the second length LT2.

In some implementations, a distance between the 1-3 string selection line cut SSLC1-3 and the second word line cut WLC2 may correspond to the second length LT2. The distance between the 1-3 string selection line cut SSLC1-3 and the first word line cut WLC1 may correspond to the fifth length LT5. In some implementations, a distance between the 1-4 string selection line cut SSLC1-4 and the second word line cut WLC2 may correspond to the first length LT1.

In some implementations, the 1-2 sub block SUB1-2 may include a first word line cut WLC1, a second word line cut WLC2, a 2-1 string selection line cut SSLC2-1, a 2-2 string selection line cut SSLC2-2, a 2-3 string selection line cut SSLC2-3, a 2-4 string selection line cut SSLC2-4, a 2-1 string selection line SSL2-1, a 2-2 string selection line SSL2-2, a 2-3 string selection line SSL2-3, a 2-4 string selection line SSL2-4, and a 2-5 string selection line SSL2-5.

In some implementations, the distance between the 2-1 string selection line cut SSLC2-1 and the third word line cut WLC3 may correspond to the first length LT1. The distance between the 2-2 string selection line cut SSLC2-12 and the third word line cut WLC3 may correspond to the second length LT2. In some implementations, the distance between the 2-2 string selection line cut SSLC2-12 and the fourth word line cut WLC4 may correspond to a fifth length LT5 further than the second length LT2.

In some implementations, the distance between the 2-3 string selection line cut SSLC2-3 and the fourth word line cut WLC4 may correspond to the second length LT2. The distance between the 2-3 string selection line cut SSLC2-3 and the third word line cut WLC3 may correspond to the fifth length LT5. In some implementations, the distance between the 2-4 string selection line cut SSLC2-4 and the fourth word line cut WLC4 may correspond to the first length LT1.

In some implementations, the 1-1 string selection line SSL1-1 may be positioned between the 1-1 string selection line cut SSLC1-1 whose distance from the first word line cut WLC1 corresponds to the first length LT1 and the first word line cut WLC1. A 1-1 string selection line SSL1-1 may be connected to a 2-3 string selection line SSL2-3 positioned between a 2-2 string selection line cut SSLC2-12 whose distance from a third word line cut WLC3 corresponds to a second length LT2 and a 2-3 string selection line cut SSLC2-3 whose distance from a third word line cut WLC3 corresponds to a fifth length LT5 farther than the second length LT2 through a contact CNT.

In some implementations, the 1-2 string selection line SSL1-2 may be positioned between the 1-1 string selection line cut SSLC1-1 whose distance from the first word line cut WLC1 corresponds to the first length LT1 and the 1-2 string selection line cut SSLC1-2 whose distance from the first word line cut WLC1 corresponds to the second length LT2. The 1-2 string selection line SSL1-2 may be connected to the 2-1 string selection line SSL2-1 positioned between the 2-1 string selection line cut SSLC2-1 whose distance from the third word line cut WLC3 corresponds to the first length LT1 and the third word line cut WLC3 through a contact CNT.

In some implementations, the 1-3 string selection line SSL1-3 may be positioned between the 1-2 string selection line cut SSLC1-2 whose distance from the first word line cut WLC1 corresponds to the second length LT2 and the 1-3 string selection line cut SSLC1-3 whose distance from the first word line cut WLC1 corresponds to the fifth length LT5. The 1-3 string selection line SSL1-3 may be connected to the 2-5 string selection line SSL2-5 positioned between the 2-4 string selection line cut SSLC2-4 whose distance from the fourth word line cut WLC4 corresponds to the first length LT1 and the fourth word line cut WLC4 through a contact CNT.

In some implementations, the 1-4 string selection line SSL1-4 may be positioned between the 1-3 string selection line cut SSLC1-3 whose distance from the second word line cut WLC2 corresponds to the second length LT2 and the 1-4 string selection line cut SSLC1-4 whose distance from the second word line cut WLC2 corresponds to the first length LT1. The 1-4 string selection line SSL1-4 may be connected to the 2-2 string selection line SSL2-12 positioned between the 2-1 string selection line cut SSLC2-1 whose distance from the third word line cut WLC3 corresponds the first length LT1 and the 2-2 string selection line cut SSLC2-12 whose distance from the third word line cut WLC3 corresponds the second length LT2 through the contact CNT.

In some implementations, the 1-5 string selection line SSL1-5 may be positioned between the 1-4 string selection line cut SSLC1-4 whose distance from the second word line cut WLC2 corresponds to the first length LT1 and the second word line cut WLC2. The 1-5 string selection line SSL1-5 may be connected to the 2-4 string selection line SSL2-4 positioned between the 2-3 string selection line cut SSLC2-3 whose distance from the second word line cut WLC2 corresponds to the second length LT2 and the 2-4 string selection line cut SSLC2-4 whose distance from the second word line cut WLC2 corresponds to the first length LT1 through a contact CNT.

In some implementations, the distance between the first word line cut WLC1 and the 1-1 string selection line SSL1-1 may correspond to the third length LT3. In some implementations, the distance between the first word line cut WLC1 and the 1-2 string selection line SSL1-2 may correspond to a fourth length LT4 farther than the third length LT3. In some implementations, the distance between the first word line cut WLC1 and the 1-3 string selection line SSL1-3 may correspond to the sixth length LT6 farther than the fourth length LT4.

In some implementations, the string selection line of the 1-1 sub block SUB1-1 whose distance from the adjacent word line cut corresponds to the third length LT3 or the sixth length LT6 among the first word line cut WLC1 and the second word line cut WLC2 may be connected to a via contact CNT to the string selection lines of the 1-2 sub block SUB1-2 whose distance from the adjacent word line cut corresponds the sixth length LT6 or the third length LT3 among the third word line cut WLC3 and the fourth word line cut WLC4.

In some implementations, the 1-1 string selection line SSL1-1 whose distance to the first word line cut WLC1 corresponds to the third length LT3 may be connected to the 2-3 string selection line SSL2-3 whose distance to the third word line cut WLC3 or the fourth word line cut WLC4 corresponds to the sixth length LT6 through the contact CNT.

In some implementations, the 1-3 string selection line SSL1-3 whose distance to the first word line cut WLC1 or the second word line cut WLC2 corresponds to the sixth length LT6 may be connected to the 2-5 string selection line SSL2-5 whose distance to the fourth word line cut WLC4 corresponds to the third length LT3 through a contact CNT.

In some implementations, the string selection line of the 1-1 sub block SUB1-1 whose distance to the adjacent word line cut corresponds to the fourth length LT4 or the third length LT3 among the first word line cut WLC1 and the second word line cut WLC2, may be connected to the string selection line of the 1-2 sub block SUB1-2 whose distance to the adjacent word line cut corresponds to the third length LT3 or the fourth length LT4 among the third word line WLC3 and the fourth word line cut WLC4 through the contact CNT.

In some implementations, the 1-2 string selection line SSL1-2 whose distance to the first word line cut WLC1 corresponds to the fourth length LT4 may be connected to the 2-1 string selection line SSL2-1 whose distance to the third word line cut WLC3 corresponds to the third length LT3 through the contact CNT.

In some implementations, the 1-5 string selection line SSL1-5 whose distance to the second word line cut WLC2 corresponds to the third length LT3 may be connected to the 2-4 string selection line SSL2-4 whose distance to the fourth word line cut WLC4 corresponds to the fourth length LT4 through the contact CNT.

In some implementations, the string selection line of the 1-1 sub block SUB1-1 whose distance to the adjacent word line cut corresponds to the fourth length LT4 among the first word line cut WLC1 and the second word line cut WLC2 may be connected to the string selection line of the 1-2 sub block SUB1-2 whose distance to the adjacent word line cut corresponds to the fourth length LT4 among the third word line cut WLC3 and the fourth word line cut WLC4 through the contact CNT.

In some implementations, the 1-4 string selection line SSL1-4 whose distance to the second word line cut WLC2 corresponds to the fourth length LT4 may be connected to the 2-2 string selection line SSL2-12 whose distance to the third word line cut WLC3 corresponds to the fourth length LT4 through the contact CNT.

In some implementations, when the number of string selection lines included in each of the 1-1 sub block SUB1-1 and the 1-2 sub block SUB1-2 is odd, the sum of the length corresponding to the distance between the one string selection line and the word line cut of the 1-1 sub block SUB1-1 and the length corresponding to the distance between the word line cut and the other string selection line of the 1-2 sub block SUB1-2 connected to the one string selection line of the 1-1 sub block SUB1-1 may be equal to the sum of the length corresponding to the distance between the word line cut and the other string selection line of the 1-1 sub block SUB1-1 and the length corresponding to the distance between the word line cut and the other string selection line of the 1-2 sub block SUB1-2 connected to the other string selection line of the 1-1 sub block SUB1-1.

In some implementations, the sum of the third length LT3 corresponding to the distance between the 1-1 string selection line SSL1-1 and the first word line cut WLC1 and the sixth length LT6 corresponding to the distance between the 2-3 string selection line SSL2-3 connected to the 1-1 string selection line SSL1-1 and the third word line cut WLC3 or the fourth word line cut WLC4 may be the same as the sum of the sixth length LT6 corresponding to the distance between the 1-3 string selection line SSL1-3 and the first word line cut WLC1 or the second word line cut WLC2 and the third length LT3 corresponding to the distance between the 2-5 string selection line SSL2-5 connected to the 1-3 string selection line SSL1-3 and the fourth word line cut WLC4.

In some implementations, the sum of the fourth length LT4 corresponding to the distance between the 1-2 string selection line SSL1-2 and the first word line cut WLC1 and the third length LT3 corresponding to the distance between the 2-1 string selection line SSL2-1 connected to the 1-2 string selection line SSL1-2 and the third word line cut WLC3 may be the same as the sum of the third length LT3 corresponding to the distance between the 1-5 string selection line SSL1-5 and the second word line cut WLC2 and the fourth length LT4 corresponding to the distance between the 2-4 string selection line SSL2-4 connected to the 1-5 string selection line SSL1-5 and the fourth word line cut WLC4.

In some implementations, the sum of the third length LT3 corresponding to the distance between the 1-1 string selection line SSL1-1 and the first word line cut WLC1 and the sixth length LT6 corresponding to the distance between the 2-3 string selection line SSL2-3 connected to the 1-1 string selection line SSL1-1 and the third word line cut WLC3 may be the same as the sum of the fourth length LT4 corresponding to the distance between the 1-4 string selection line SSL1-4 and the second word line cut WLC2 and the fourth length LT4 corresponding to the distance between the 2-2 string selection line SSL2-12 connected to the 1-4 string selection line SSL1-4 and the third word line cut WLC3.

In some implementations, when the number of string selection lines included in each of the 1-1 sub block SUB1-1 and the 1-2 sub block SUB1-2 is odd, the difference between the sum of the length corresponding to the distance between the one string selection line and the word line cut of the 1-1 sub block SUB1-1 and the length corresponding to the distance between the one string selection line and the word line cut of the 1-2 sub block SUB1-2 connected to the one string selection line of the 1-1 sub block SUB1-1 and the sum of the length corresponding to the distance between the word line cut and the other string selection line of the 1-1 sub block SUB1-1 and the length corresponding to the distance between the word line cut and the other string selection line of the 1-2 sub block SUB1-2 connected to the other string selection line of the 1-1 sub block SUB1-1 may correspond to the sum of the first length LT1 and the string selection line cut length LT_SSLC of FIG. 8.

In some implementations, the difference between the sum of the third length LT3 corresponding to the distance between the 1-1 string selection line SSL1-1 and the first word line cut WLC1 and the 2-3 string selection line SSL2-3 connected to the 1-1 string selection line SSL1-1 and the sixth length LT6 corresponding to the distance between the third word line cut WLC3 or the fourth word line cut WLC4 and the sum of the fourth length LT4 corresponding to the distance between the 1-2 string selection line SSL1-2 and the first word line cut WLC1, and the third length LT3 corresponding to the distance between the 2-1 string selection line SSL2-1 and the third word line cut WLC3 connected to the 1-2 string selection line SSL1-2 may correspond to the difference between the sixth length LT6 and the fourth length LT4. The difference between the sixth length LT6 and the fourth length LT4 may correspond to the sum of the first length LT1 and the string selection line cut length LT_SSLC of FIG. 8.

In some implementations, the difference between the sum of the fourth length LT4 corresponding to the distance between the 1-2 string selection line SSL1-2 and the first word line cut WLC1 and the third length LT3 corresponding to the distance between the 2-1 string selection line SSL2-1 and the third word line cut WLC3 connected to the 1-2 string selection line SSL1-2 and the sum of the fourth length LT4 corresponding to the distance between the 1-4 string selection line SSL1-4 and the second word line cut WLC2, and the third length LT3 corresponding to the distance between the 2-2 string selection line SSL2-12 and the third word line cut WLC3 connected to the 1-4 string selection line SSL1-4 may correspond to the difference between the fourth length LT4 and the third length LT3. The difference between the fourth length LT4 and the third length LT3 may correspond to the sum of the first length LT1 and the string selection line cut length LT_SSLC of FIG. 8.

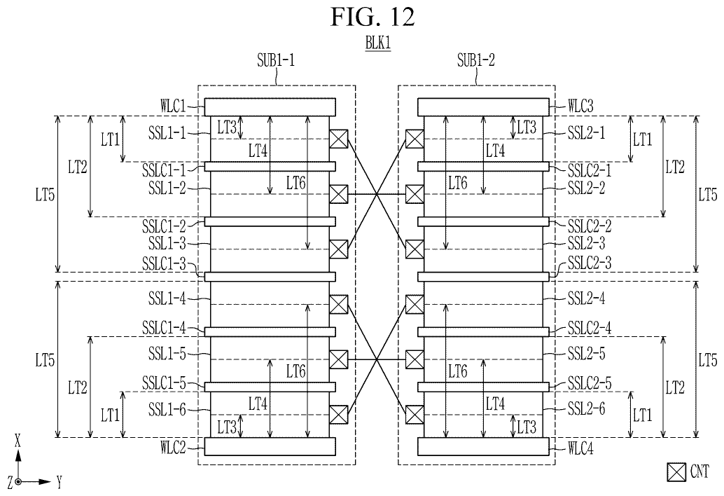

FIG. 12 is a drawing for explaining the connection relationship among six string selection lines included in each of a plurality of sub blocks according to some implementations.

Referring to FIG. 12, the 1-1 sub block SUB1-1 may include a first word line cut WLC1, a second word line cut WLC2, a 1-1 string selection line cut SSLC1-1, a 1-2 string selection line cut SSLC1-2, a 1-3 string selection line cut SSLC1-3, a 1-4 string selection line cut SSLC1-4, a 1-5 string selection line cut SSLC1-5, a 1-1 string selection line SSL1-1, a 1-2 string selection line SSL1-2, a 1-3 string selection line SSL1-3, a 1-4 string selection line SSL1-4, a 1-5 string selection line SSL1-5, and a 1-6 string selection line SSL1-6.

In some implementations, the 1-2 sub block SUB1-2 may include a first word line cut WLC1, a second word line cut WLC2, a 2-1 string selection line cut SSLC2-1, a 2-2 string selection line cut SSLC2-2, a 2-3 string selection line cut SSLC2-3, a 2-4 string selection line cut SSLC2-4, a 2-5 string selection line cut SSLC2-5, a 2-1 string selection line SSL2-1, a 2-2 string selection line SSL2-2, a 2-3 string selection line SSL2-3, a 2-4 string selection line SSL2-4, a 2-5 string selection line SSL2-5, and a 2-6 string selection line SSL2-6.

In some implementations, the 1-1 string selection line SSL1-1 may be positioned between the 1-1 string selection line cut SSLC1-1 and the first word line cut WLC1 whose distance from the first word line cut WLC1 corresponds to the first length LT1. A 1-1 string selection line SSL1-1 may be connected to a 2-3 string selection line SSL2-3 positioned between a 2-2 string selection line cut SSLC2-12 whose distance from a third word line cut WLC3 corresponds to a second length LT2 and a 2-3 string selection line cut SSLC2-3 whose distance from a third word line cut WLC3 corresponds to a fifth length LT5 farther than the second length LT2 through a contact CNT.

In some implementations, the 1-2 string selection line SSL1-2 may be positioned between the 1-2 string selection line cut SSLC1-2 and the 1-1 string selection line cut SSLC1-1 in which a distance from the first word line cut WLC1 corresponds to the second length LT2. The 1-2 string selection line SSL1-2 may be connected to the 2-2 string selection line SSL2-12 positioned between the 2-1 string selection line cut SSLC2-1 whose distance from the third word line cut WLC3 corresponds to the first length LT1 and the 2-2 string selection line cut SSLC2-12 through a contact CNT.

In some implementations, the 1-3 string selection line SSL1-3 may be positioned between the 1-3 string selection line cut SSLC1-3 whose distance from the first word line cut WLC1 corresponds to the fifth length LT5 and the 1-2 string selection line cut SSLC1-2. The 1-3 string selection line SSL1-3 may be connected to the 2-1 string selection line SSL2-1 positioned between the third word line cut WLC3 and the 2-1 string selection line cut SSLC2-1 through a contact CNT.

In some implementations, the 1-4 string selection line SSL1-4 may be positioned between the 1-4 string selection line cut SSLC1-4 whose distance from the second word line cut WLC2 corresponds to the second length LT2 and the 1-3 string selection line cut SSLC1-3 whose distance from the second word line cut WLC2 corresponds to the fifth length LT5. The 1-4 string selection line SSL1-4 may be connected to the 2-6 string selection line SSL2-6 positioned between the 2-5 string selection line cut SSLC2-5 whose distance from the fourth word line cut WLC4 corresponds to the first length LT1 and the fourth word line cut WLC4 through a contact CNT.

In some implementations, the 1-5 string selection line SSL1-5 may be positioned between the 1-5 string selection line cut SSLC1-5 whose distance corresponds to the first length LT1 from the second word line cut WLC2 and the 1-4 string selection line cut SSLC1-4. The 1-5 string selection line SSL1-5 may be connected to the 2-5 string selection line SSL2-5 positioned between the 2-4 string selection line cut SSLC2-4 whose distance from the fourth word line cut WLC4 corresponds to the second length LT2 and the 2-5 string selection line cut SSLC2-5 through a contact CNT.

In some implementations, the 1-6 string selection line SSL1-6 may be positioned between the 1-5 string selection line cut SSLC1-5 and the second word line cut WLC2. The 1-6 string selection line SSL1-6 may be connected to the 2-4 string selection line SSL2-4 positioned between the 2-3 string selection line cut SSLC2-3 whose distance from the fourth word line cut WLC4 corresponds to the fifth length LT5 and the 2-4 string selection line cut SSLC2-4 through a contact CNT.

In some implementations, the string selection line of the 1-1 sub block SUB1-1 whose distance to the adjacent word line cut corresponds to the third length LT3 or the sixth length LT6 among the first word line cut WLC1 and the second word line cut WLC2 may be connected to the string selection line of the 1-2 sub block SUB1-2 whose distance to the adjacent word line cut corresponds to the sixth length LT6 or the third length LT3 among the third word line cut WLC3 and the fourth word line cut WLC4 through the contact CNT.

In some implementations, the 1-1 string selection line SSL1-1 whose distance to the first word line cut WLC1 corresponds to the third length LT3 may be connected to the 2-3 string selection line SSL2-3 whose distance to the third word line cut WLC3 corresponds to the sixth length LT6 through the contact CNT.

In some implementations, the 1-6 string selection line SSL1-6 whose distance to the second word line cut WLC2 corresponds to the third length LT3 may be connected to the 2-4 string selection line SSL2-4 whose distance to the fourth word line cut WLC4 corresponds to the sixth length LT6 through the contact CNT.

In some implementations, the 1-3 string selection line SSL1-3 whose distance to the first word line cut WLC1 corresponds to the sixth length LT6 may be connected to the 2-1 string selection line SSL2-1 whose distance to the third word line cut WLC3 corresponds to the third length LT3 through the contact CNT.

In some implementations, the 1-4 string selection line SSL1-4 whose distance to the second word line cut WLC2 corresponds to the sixth length LT6 may be connected to the 2-6 string selection line SSL2-6 whose distance to the fourth word line cut WLC4 corresponds to the third length LT3 through the contact CNT.

In some implementations, the string selection line of the 1-1 sub block SUB1-1 whose distance to the adjacent word line cut corresponds to the fourth length LT4 among the first word line cut WLC1 and the second word line cut WLC2 may be connected to the string selection line of the 1-2 sub block SUB1-2 whose distance to the adjacent word line cut corresponds to the fourth length LT4 among the third word line WLC3 cut and the fourth word line cut WLC4 through the contact CNT.

In some implementations, the 1-2 string selection line SSL1-2 whose distance to the first word line cut WLC1 corresponds to the fourth length LT4 may be connected to the 2-2 string selection line SSL2-12 whose distance to the third word line cut WLC3 corresponds to the fourth length LT4 through the contact CNT.

In some implementations, the 1-5 string selection line SSL1-5 whose distance to the second word line cut WLC2 corresponds to the fourth length LT4 may be connected to the 2-5 string selection line SSL2-5 whose distance to the fourth word line cut WLC4 corresponds to the fourth length LT4 through the contact CNT.

In some implementations, when the number of string selection lines included in each of the 1-1 sub block SUB1-1 and the 1-2 sub block SUB1-2 is even, the sum of the length corresponding to the distance between the one string selection line and the word line cut of the 1-1 sub block SUB1-1 and the length corresponding to the distance between the word line cut and the other string selection line of the 1-2 sub block SUB1-2 connected to the one string selection line of the 1-1 sub block SUB1-1 may be the same as the sum of the length corresponding to the distance between the word line cut and the other string selection line of the 1-1 sub block SUB1-1 and the length corresponding to the distance between the word line cut and the other string selection line of the 1-2 sub block SUB1-2 connected to the other string selection line of the 1-1 sub block SUB1-1.

In some implementations, the sum of the third length LT3 corresponding to the distance between the 1-1 string selection line SSL1-1 and the first word line cut WLC1 and the sixth length LT6 corresponding to the distance between the 2-3 string selection line SSL2-3 connected to the 1-1 string selection line SSL1-1 and the third word line cut WLC3 may be the same as the sum of the fourth length LT4 corresponding to the distance between the 1-2 string selection line SSL1-2 and the first word line cut WLC1 and the fourth length LT4 corresponding to the distance between the 2-2 string selection line SSL2-12 connected to the 1-2 string selection line SSL1-2 and the third word line cut WLC3.

In some implementations, the sum of the third length LT3 corresponding to the distance between the 1-1 string selection line SSL1-1 and the first word line cut WLC1 and the sixth length LT6 corresponding to the distance between the 2-3 string selection line SSL2-3 connected to the 1-1 string selection line SSL1-1 and the third word line cut WLC3 may be the same as the sum of the sixth length LT6 corresponding to the distance between the 1-3 string selection line SSL1-3 and the first word line cut WLC1 and the third length LT3 corresponding to the distance between the 2-1 string selection line SSL2-1 connected to the 1-3 string selection line SSL1-3 and the third word line cut WLC3.

In some implementations, the sum of the fourth length LT4 corresponding to the distance between the 1-2 string selection line SSL1-2 and the first word line cut WLC1 and the fourth length LT4 corresponding to the distance between the 2-2 string selection line SSL2-12 connected to the 1-2 string selection line SSL1-2 and the third word line cut WLC3 may be the same as the sum of the sixth length LT6 corresponding to the distance between the 1-3 string selection line SSL1-3 and the first word line cut WLC1 and the third length LT3 corresponding to the distance between the 2-1 string selection line SSL2-1 connected to the 1-3 string selection line SSL1-3 and the third word line cut WLC3.

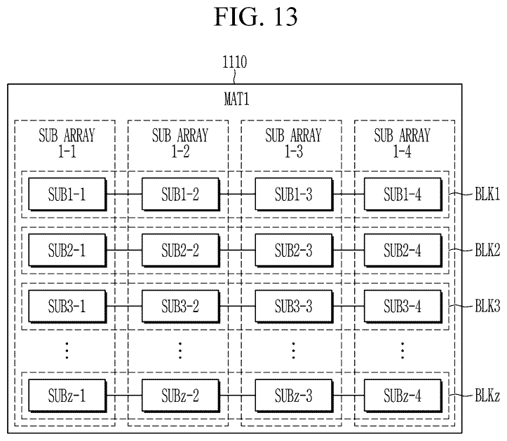

FIG. 13 is a drawing for explaining another example of multiple sub blocks according to some implementations.

Referring to FIG. 13, the first mat 1110 may include a 1-1 sub array SUB ARRAY1-1, a 1-2 sub array SUB ARRAY1-2, a 1-3 sub array SUB ARRAY1-3, and a 1-4 sub array SUB ARRAY1-4. The 1-1 sub array SUB ARRAY1-1, the 1-2 sub array SUB ARRAY1-2, the 1-3 sub array SUB ARRAY1-3, and the 1-4 sub array SUB ARRAY1-4 may include a plurality of memory blocks BLK1 to BLKz.

In some implementations, each of the plurality of memory blocks BLK1 to BLKz may include a plurality of sub blocks. In some implementations, the first memory block BLK1 may include a 1-1 sub block SUB1-1, a 1-2 sub block SUB1-2, a 1-3 sub block SUB1-3, and a 1-4 sub block SUB1-4. In some implementations, the second memory block BLK2 may include a 2-1 sub block SUB2-1, a 2-2 sub block SUB2-2, a 2-3 sub block SUB2-3, and a 2-4 sub block SUB2-4.

In some implementations, the 1-1 sub array SUB ARRAY1-1 may include one sub block included in each of the plurality of memory blocks BLK1 to BLKz. In some implementations, the 1-1 sub array SUB ARRAY1-1 may include the 1-1 sub block SUB1-1 included in the first memory block BLK1. In some implementations, the 1-1 sub array SUB ARRAY1-1 may include the 2-1 sub block SUB2-1 included in the second memory block BLK2.

In some implementations, the 1-2 sub array SUB ARRAY1-2 may include another sub block included in each of the plurality of memory blocks. In some implementations, the 1-2 sub array SUB ARRAY1-2 may include a 1-2 sub block SUB1-2 included in the first memory block BLK1. In some implementations, the 1-2 sub array SUB ARRAY1-2 may include a 2-2 sub block SUB2-12 included in the second memory block BLK2.

In some implementations, the 1-3 sub array SUB ARRAY1-3 may include another sub block included in each of the plurality of memory blocks. In some implementations, the 1-3 sub array SUB ARRAY1-3 may include the 1-3 sub block SUB1-3 included in the first memory block BLK1. In some implementations, the 1-3 sub array SUB ARRAY1-3 may include the 2-3 sub block SUB2-3 included in the second memory block BLK2.

In some implementations, the 1-4 sub array SUB ARRAY1-4 may include another sub block included in each of the plurality of memory blocks. In some implementations, the 1-4 sub array SUB ARRAY1-4 may include the 1-4 sub block SUB1-4 included in the first memory block BLK1. In some implementations, the 1-4 sub array SUB ARRAY1-4 may include the 2-4 sub block SUB2-4 included in the second memory block BLK2.

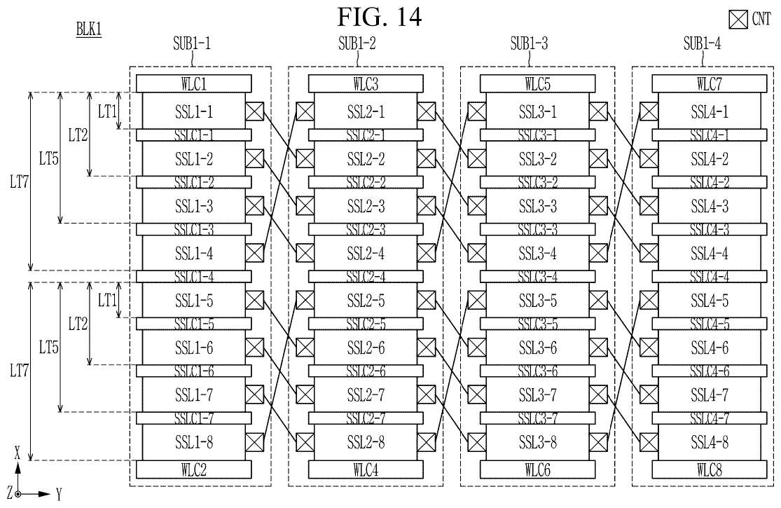

FIG. 14 is a drawing for explaining the connection relationship among eight string selection lines included in each of a plurality of sub blocks according to some implementations.

Referring to FIG. 14, the 1-1 sub block SUB1-1 may include a first word line cut WLC1, a second word line cut WLC2, a 1-1 string selection line cut SSLC1-1, a 1-2 string selection line cut SSLC1-2, a 1-3 string selection line cut SSLC1-3, a 1-4 string selection line cut SSLC1-4, a 1-5 string selection line cut SSLC1-5, a 1-6 string selection line cut SSLC1-6, a 1-7 string selection line cut SSLC1-7, a 1-1 string selection line SSL1-1, a 1-2 string selection line SSL1-2, a 1-3 string selection line SSL1-3, a 1-4 string selection line SSL1-4, a 1-5 string selection line SSL1-5, a 1-6 string selection line SSL1-6, a 1-7 string selection line SSL1-7, and a 1-8 string selection line SSL1-8.

In some implementations, the 1-2 sub block SUB1-2 may include a third word line cut WLC3, a fourth word line cut WLC4, a 2-1 string selection line cut SSLC2-1, a 2-2 string selection line cut SSLC2-2, a 2-3 string selection line cut SSLC2-3, a 2-4 string selection line cut SSLC2-4, a 2-5 string selection line cut SSLC2-5, a 2-6 string selection line cut SSLC2-6, a 2-7 string selection line cut SSLC2-7, a 2-1 string selection line SSL2-1, a 2-2 string selection line SSL2-2, a 2-3 string selection line SSL2-3, a 2-4 string selection line SSL2-4, a 2-5 string selection line SSL2-5, a 2-6 string selection line SSL2-6, a 2-7 string selection line SSL2-7, and a 2-8 string selection line SSL2-8.

In some implementations, the 1-3 sub block SUB1-3 may include a fifth word line cut WLC5, a sixth word line cut WLC6, a 3-1 string selection line cut SSLC3-1, a 3-2 string selection line cut SSLC3-2, a 3-3 string selection line cut SSLC3-3, a 3-4 string selection line cut SSLC3-4, a 3-5 string selection line cut SSLC3-5, a 3-6 string selection line cut SSLC3-6, a 3-7 string selection line cut SSLC3-7, a 3-1 string selection line SSL3-1, a 3-2 string selection line SSL3-2, a 3-3 string selection line SSL3-3, a 3-4 string selection line SSL3-4, a 3-5 string selection line SSL3-5, a 3-6 string selection line SSL3-6, a 3-7 string selection line SSL3-7, and a 3-8 string selection line SSL3-8.

In some implementations, the 1-4 sub block SUB1-4 may include a seventh word line cut WLC7, an eighth word line cut WLC8, a 4-1 string selection line cut SSLC4-1, a 4-2 string selection line cut SSLC4-2, a 4-3 string selection line cut SSLC4-3, a 4-4 string selection line cut SSLC4-4, a 4-5 string selection line cut SSLC4-5, a 4-6 string selection line cut SSLC4-6, a 4-7 string selection line cut SSLC4-7, a 4-1 string selection line SSL4-1, a 4-2 string selection line SSL4-2, a 4-3 string selection line SSL4-3, a 4-4 string selection line SSL4-4, a 4-5 string selection line SSL4-5, a 4-6 string selection line SSL4-6, a 4-7 string selection line SSL4-7, and a 4-8 string selection line SSL4-8.

In some implementations, the 1-1 string selection line SSL1-1 may be positioned between the 1-1 string selection line cut SSLC1-1 whose distance from the first word line cut WLC1 corresponds to the first length LT1 and the first word line cut WLC1. The 1-1 string selection line SSL1-1 may be connected to the 2-2 string selection line SSL2-12 positioned between the 2-2 string selection line cut SSLC2-12 whose distance from the third word line cut WLC3 corresponds to the second length LT2 and the 2-1 string selection line cut SSLC2-1 through the contact CNT.

In some implementations, a 2-2 string selection line SSL2-12 may be connected to a 3-3 string selection line SSL3-13 located between a 3-2 string selection line cut SSLC3-2 whose distance from the fifth word line cut WLC5 corresponds to the second length LT2 and a 3-3 string selection line cut SSLC3-13 whose distance from the fifth word line cut WLC5 corresponds to the fifth length LT5 through a contact CNT.

In some implementations, a 3-3 string selection line SSL3-13 may be connected to a 4-4 string selection line SSL4-14 positioned between a 4-3 string selection line cut SSLC4-3 whose distance from a seventh word line cut WLC7 corresponds to a fifth length LT5 and a 4-4 string selection line cut SSLC4-14 whose distance from a seventh word line cut WLC7 corresponds to a seventh length LT7 farther than the fifth length LT5 through a contact CNT.

In some implementations, the 1-2 string selection line SSL1-2 may be positioned between the 1-1 string selection line cut SSLC1-1 whose distance from the first word line cut WLC1 corresponds to the first length LT1 and the 1-2 string selection line cut SSLC1-2 whose distance from the first word line cut WLC1 corresponds to the second length LT2. The 1-2 string selection line SSL1-2 may be connected to the 2-3 string selection line SSL2-3 positioned between the 2-2 string selection line cut SSLC2-12 whose distance from the third word line cut WLC3 corresponds to the second length LT2 and the 2-3 string selection line cut SSLC2-3 whose distance from the third word line cut WLC3 corresponds to the fifth length LT5 through a contact CNT.

In some implementations, a 2-3 string selection line SSL2-3 may be connected to a 3-4 string selection line SSL3-4 positioned between a 3-3 string selection line cut SSLC3-13 whose distance from a fifth word line cut WLC5 corresponds to a fifth length LT5 and a 3-4 string selection line cut SSLC3-4 whose distance from a fifth word line cut WLC5 corresponds to a seventh length LT7 farther than the fifth length LT5, through a contact CNT.

In some implementations, the 3-4 string selection line SSL3-4 may be connected to the 4-1 string selection line SSL4-1 positioned between the 4-1 string selection line cut SSLC4-1 whose distance from the seventh word line cut WLC7 corresponds to the first length LT1 and the seventh word line cut WLC7 through a contact CNT.

In some implementations, a 1-1 string selection line SSL1-1 whose distance from the first word line cut WLC1 corresponds to a third length may be connected to a 2-2 string selection line SSL2-12 whose distance from the third word line cut WLC3 corresponds to a fourth length farther than the third length through a contact CNT.

In some implementations, the 2-2 string selection line SSL2-12 may be connected to the 3-3 string selection line SSL3-13 whose distance from the fifth word line cut WLC5 corresponds to the sixth length farther than the fourth length through a contact CNT.

In some implementations, the 3-3 string selection line SSL3-13 may be connected to the 4-4 string selection line SSL4-14 whose distance from the seventh word line cut WLC7 corresponds to the eighth length farther than the sixth length through a contact CNT.

In some implementations, the 1-2 string selection line SSL1-2 whose distance from the first word line cut WLC1 corresponds to the fourth length LT4 may be connected to the 2-3 string selection line SSL2-3 whose distance from the third word line cut WLC3 corresponds to the sixth length farther than the fourth length through the contact CNT.

In some implementations, the 2-3 string selection line SSL2-3 may be connected to the 3-4 string selection line SSL3-4 whose distance from the fifth word line cut WLC5 corresponds to the eighth length farther than the sixth length through a contact CNT.

In some implementations, the 3-4 string selection line SSL3-4 may be connected to a 4-1 string selection line SSL4-1 whose distance from the seventh word line cut WLC7 corresponds to a third length closer than the fourth length through a contact CNT.

In some implementations, when the number of string selection lines included in each of the 1-1 sub block SUB1-1, the 1-2 sub block SUB1-2, the 1-3 sub block SUB1-3, and the 1-4 sub block SUB1-4 is even, the sum of the length corresponding to the distance between one string selection line and a word line cut of the 1-1 sub block SUB1-1, the length corresponding to the distance between one string selection line of the 1-2 sub block SUB1-2 connected to the string selection line of the 1-1 sub block SUB1-1 and a word line cut, the length corresponding to the distance between one string selection line of the 1-3 sub block SUB1-3 connected to the string selection line of the 1-2 sub block SUB1-2 and a word line cut, and the length corresponding to the distance between one string selection line of the 1-4 sub block SUB1-4 connected to the string selection line of the 1-3 sub block SUB1-3 and a word line cut may be same as the sum of the length corresponding to the distance between another string selection line and a word line cut of the 1-1 sub block SUB1-1, the length corresponding to the distance between another string selection line of the 1-2 sub block SUB1-2 connected to another string selection line of the 1-1 sub block SUB1-1 and a word line cut, the length corresponding to the distance between another string selection line of the 1-3 sub block SUB1-3 connected to another string selection line of the 1-2 sub block SUB1-2 and a word line cut, and the length corresponding to the distance between another string selection line of the 1-4 sub block SUB1-4 connected to another string selection line of the 1-3 sub block SUB1-3 and a word line cut.

In some implementations, the sum of the third length corresponding to the distance between the 1-1 string selection line SSL1-1 and the first word line cut WLC1, the fourth length corresponding to the distance between the 2-2 string selection line SSL2-12 connected to the 1-1 string selection line SSL1-1 and the third word line cut WLC3, the sixth length corresponding to the distance between the 3-3 string selection line SSL3-13 connected to the 2-2 string selection line SSL2-12 and the fifth word line cut WLC5, and the eighth length corresponding to the distance between the 4-4 string selection line SSL4-14 connected to the 3-3 string selection line SSL3-13 and the seventh word line cut WLC7 may be the same as the sum of the fourth length corresponding to the distance between the 1-2 string selection line SSL1-2 and the first word line cut WLC1, the sixth length corresponding to the distance between the 2-3 string selection line SSL2-3 connected to the 1-2 string selection line SSL1-2 and the third word line cut WLC3, the eighth length corresponding to the distance between the 3-4 string selection line SSL3-4 connected to the 2-3 string selection line SSL2-3 and the fifth word line cut WLC5, and the third length corresponding to the distance between the 4-1 string selection line SSL4-1 connected to the 3-4 string selection line SSL3-4 and the seventh word line cut WLC7.

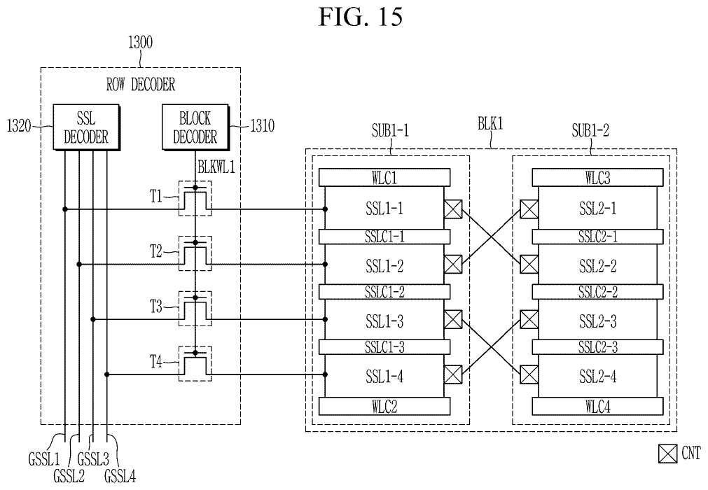

FIG. 15 is a diagram for explaining a connection relationship between a plurality of sub blocks and a row decoder according to some implementations.

Referring to FIG. 15, the first memory block BLK1 may include a 1-1 sub block SUB1-1 and a 1-2 sub block SUB1-2. The 1-1 sub block SUB1-1 may be included in the 1-1 sub array SUB ARRAY1-1. The 1-2 sub block SUB1-2 may be included in the 1-2 sub array SUB ARRAY1-2.

In some implementations, the 1-1 sub block SUB1-1 may include a first word line cut WLC1, a second word line cut WLC2, a 1-1 string selection line cut SSLC1-1, a 1-2 string selection line cut SSLC1-2, a 1-3 string selection line cut SSLC1-3, a 1-1 string selection line SSL1-1, a 1-2 string selection line SSL1-2, a 1-3 string selection line SSL1-3, and a 1-4 string selection line SSL1-4.

In some implementations, the 1-2 sub block SUB1-2 may include a third word line cut WLC3, a fourth word line cut WLC4, a 2-1 string selection line cut SSLC2-1, a 2-2 string selection line cut SSLC2-2, a 2-3 string selection line cut SSLC2-3, a 2-1 string selection line SSL2-1, a 2-2 string selection line SSL2-2, a 2-3 string selection line SSL2-3, and a 2-4 string selection line SSL2-4.

In some implementations, a row decoder 1300 may include a block decoder 1310, a string selection line decoder 1320, a first transistor T1, a second transistor T2, a third transistor T3, and a fourth transistor T4.

In some implementations, the first transistor T1, the second transistor T2, the third transistor T3, and the fourth transistor T4 may be commonly connected to the first block word line BLKWL1.

In some implementations, the first transistor T1 may be connected to the first global string selection line GSSL1 and the 1-1 string selection line SSL1-1. In some implementations, the 1-1 string selection line SSL1-1 may be connected to the 2-2 string selection line SSL2-12 through a contact CNT.

In some implementations, the second transistor T2 may be connected to the second global string selection line GSSL2 and the 1-2 string selection line SSL1-2. The 1-2 string selection line SSL1-2 may be connected to the 2-1 string selection line SSL2-1 through a contact CNT.

In some implementations, the third transistor T3 may be connected to the third global string selection line GSSL3 and the 1-3 string selection line SSL1-3. The 1-3 string selection line SSL1-3 may be connected to the 2-4 string selection line SSL2-4 through a contact CNT.

In some implementations, the fourth transistor T4 may be connected to the fourth global string selection line GSSL4 and the 1-4 string selection line SSL1-4. The 1-4 string selection line SSL1-4 may be connected to the 2-3 string selection line SSL2-3 through a contact CNT.

In some implementations, the block decoder 1310 may be coupled to the first block word line BLKWL1. The first block word line BLKWL1 may be a word line for selecting the first memory block BLK1.

In some implementations, the block decoder 1310 may provide a block selection signal for selecting the first memory block BLK1 to the first block word line BLKWL1. The first transistor T1, the second transistor T2, the third transistor T3, and the fourth transistor T4 may be turned on according to a block selection signal.

In some implementations, the string selection line decoder 1320 may be connected to a first global string selection line GSSL1, a second global string selection line GSSL2, a third global string selection line GSSL3, and a fourth global string selection line GSSL4. The first global string selection line GSSL1, the second global string selection line GSSL2, the third global string selection line GSSL3, and the fourth global string selection line GSSL4 may be connected to a plurality of string selection lines included in each of the plurality of memory blocks.

In some implementations, the string selection line decoder 1320 may select one of a first global string selection line GSSL1, a second global string selection line GSSL2, a third global string selection line GSSL3, and a fourth global string selection line GSSL4.

In some implementations, the string selection line decoder 1320 may provide a string selection line signal for selecting a string selection line to one of the first to fourth global string selection lines GSSL1 to GSSL4.

In some implementations, when a string selection line signal is provided to the first global string selection line GSSL1, the 1-1 string selection line SSL1-1 and the 2-2 string selection line SSL2-12 may be selected. In some implementations, when a string selection line signal is provided to the second global string selection line GSSL2, the 1-2 string selection line SSL1-2 and the 2-1 string selection line SSL2-1 may be selected. In some implementations, when a string selection line signal is provided to the third global string selection line GSSL3, the 1-3 string selection line SSL1-3 and the 2-4 string selection line SSL2-4 may be selected. In some implementations, when a string selection line signal is provided to the fourth global string selection line GSSL4, the 1-4 string selection line SSL1-4 and the 2-3 string selection line SSL2-3 may be selected.

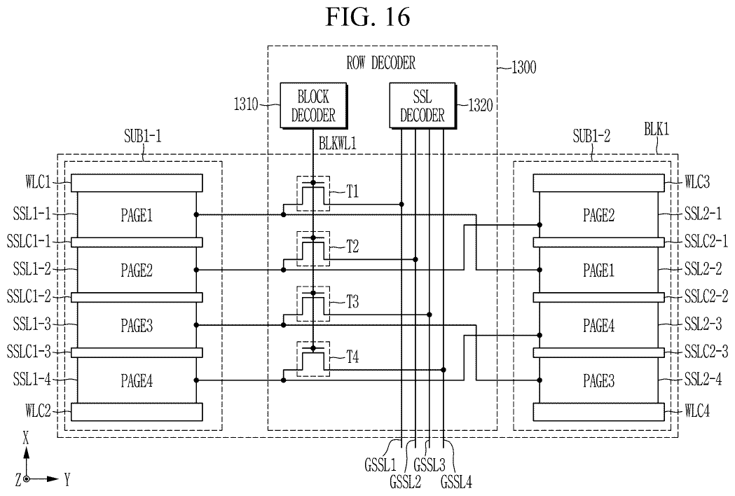

FIG. 16 is a diagram illustrating another example of a connection relationship between a plurality of sub blocks and a row decoder according to some implementations.

Referring to FIG. 16, the row decoder 1300 may be located between the 1-1 sub array SUB ARRAY1-1 including the 1-1 sub block SUB1-1 and the 1-2 sub array SUB ARRAY1-2 including the 1-2 sub block SUB1-2. In some implementations, the first transistor T1, the second transistor T2, the third transistor T3, and the fourth transistor T4 may be positioned between the 1-1 sub block SUB1-1 and the 1-2 sub block SUB1-2. In some implementations, the first block word line BLKWL1, the first global string selection line GSSL1, the second global string selection line GSSL2, the third global string selection line GSSL3, and the fourth global string selection line GSSL4 may be positioned between the 1-1 sub block SUB1-1 and the 1-2 sub block SUB1-2.

In some implementations, the gate electrode of the first transistor T1, the gate electrode of the second transistor T2, the gate electrode of the third transistor T3, and the gate electrode of the fourth transistor T4 may be commonly connected to the first block word line BLKWL1.

In some implementations, one electrode of the first transistor T1 may be connected to the 1-1 string selection line SSL1-1 and the 2-2 string selection line SSL2-2. The other electrode of the first transistor T1 may be connected to the first global string selection line GSSL1.

In some implementations, one electrode of the second transistor T2 may be connected to the 1-2 string selection line SSL1-2 and the 2-1 string selection line SSL2-1. The other electrode of the second transistor T2 may be connected to the second global string selection line GSSL2.

In some implementations, one electrode of the third transistor T3 may be connected to the 1-3 string selection line SSL1-3 and the 2-4 string selection line SSL2-4. The other electrode of the third transistor T3 may be connected to the third global string selection line GSSL3.

In some implementations, one electrode of the fourth transistor T4 may be connected to the 1-4 string selection line SSL1-4 and the 2-3 string selection line SSL2-3. The other electrode of the fourth transistor T4 may be connected to the fourth global string selection line GSSL4.

In some implementations, memory cells connected to the 1-1 string selection line SSL1-1 and the 2-2 string selection line SSL2-12 and connected to one of a plurality of word lines may be configured as a first page PAGE1. In some implementations, when a block selection signal is provided through the first block word line BLKWL1 and a string selection line signal is provided through the first global string selection line GSSL1, data may be stored in the first page PAGE1 or data stored in the first page PAGE1 may be read.

In some implementations, memory cells connected to the 1-2 string selection line SSL1-2 and the 2-1 string selection line SSL2-1 and one of a plurality of word lines may be configured as a second page PAGE2. In some implementations, when a block selection signal is provided through the first block word line BLKWL1 and a string selection line signal is provided through the second global string selection line GSSL2, data may be stored in the second page PAGE2 or data stored in the second page PAGE2 may be read.

In some implementations, memory cells connected to the 1-3 string selection line SSL1-3 and the 2-4 string selection line SSL2-4 and one of a plurality of word lines may be configured as a third page PAGE3. In some implementations, when a block selection signal is provided through the first block word line BLKWL1 and a string selection line signal is provided through the third global string selection line GSSL3, data may be stored in the third page PAGE3 or data stored in the third page PAGE3 may be read.

In some implementations, memory cells connected to the 1-4 string selection line SSL1-4 and the 2-3 string selection line SSL2-3 and one of a plurality of word lines may be configured as a fourth page PAGE4. In some implementations, when a block selection signal is provided through the first block word line BLKWL1 and a string selection line signal is provided through the fourth global string selection line GSSL4, data may be stored in the fourth page PAGE4 or data stored in the fourth page PAGE4 may be read.

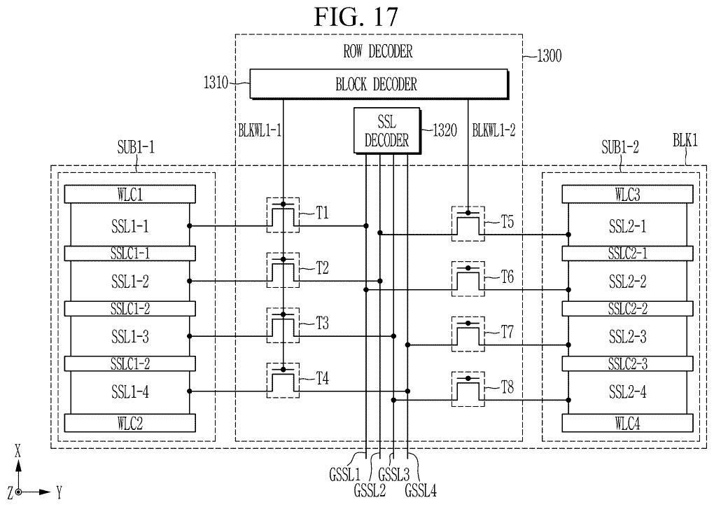

FIG. 17 is a diagram illustrating another example of a connection relationship between a plurality of sub blocks and a row decoder according to some implementations.

Referring to FIG. 17, a row decoder 1300 may include a block decoder 1310, a string selection line decoder 1320, a first transistor T1, a second transistor T2, a third transistor T3, a fourth transistor T4, a fifth transistor T5, a sixth transistor T6, a seventh transistor T7, and an eighth transistor T8.

In some implementations, the first transistor T1, the second transistor T2, the third transistor T3, and the fourth transistor T4 may be commonly connected to the 1-1 block word line BLKWL1-1. The 1-1 block word line BLKWL1-1 may be a word line for selecting the first memory block BLK1.

In some implementations, the fifth transistor T5, the sixth transistor T6, the seventh transistor T7, and the eighth transistor T8 may be commonly connected to the 1-2 block word line BLKWL1-2. The 1-2 block word line BLKWL1-2 may be a word line for selecting the first memory block BLK1.

In some implementations, the first transistor T1 may be connected to the 1-1 string selection line SSL1-1 and the first global string selection line GSSL1. The sixth transistor T6 may be connected to the first global string selection line GSSL1 and the 2-2 string selection line SSL2-2. When a block selection signal for selecting the first memory block BLK1 is provided to the 1-1 block word line BLKWL1-1 and the 1-2 block word line BLKWL1-2, and a string selection line signal is provided to the first global string selection line GSSL1, the 1-1 string selection line SSL1-1 and the 2-2 string selection line SSL2-12 may be selected.

In some implementations, the second transistor T2 may be connected to the 1-2 string selection line SSL1-2 and the second global string selection line GSSL2. The fifth transistor T5 may be connected to the second global string selection line GSSL2 and the 2-1 string selection line SSL2-1. When a block selection signal for selecting the first memory block BLK1 is provided to the 1-1 block word line BLKWL1-1 and the 1-2 block word line BLKWL1-2, and a string selection line signal is provided to the second global string selection line GSSL2, the 1-2 string selection line SSL1-2 and the 2-1 string selection line SSL2-1 may be selected.

In some implementations, the third transistor T3 may be connected to the 1-3 string selection line SSL1-3 and the third global string selection line GSSL3. The eighth transistor T8 may be connected to the third global string selection line GSSL3 and the 2-4 string selection line SSL2-4. When a block selection signal for selecting the first memory block BLK1 is provided to the 1-1 block word line BLKWL1-1 and the 1-2 block word line BLKWL1-2, and a string selection line signal is provided to the third global string selection line GSSL3, the 1-3 string selection line SSL1-3 and the 2-4 string selection line SSL2-4 may be selected.

In some implementations, the fourth transistor T4 may be connected to the 1-4 string selection line SSL1-4 and the fourth global string selection line GSSL4. The seventh transistor T7 may be connected to the fourth global string selection line GSSL4 and the 2-3 string selection line SSL2-3. When a block selection signal for selecting the first memory block BLK1 is provided to the 1-1 block word line BLKWL1-1 and the 1-2 block word line BLKWL1-2, and a string selection line signal is provided to the fourth global string selection line GSSL4, the 1-4 string selection line SSL1-4 and the 2-3 string selection line SSL2-3 may be selected.

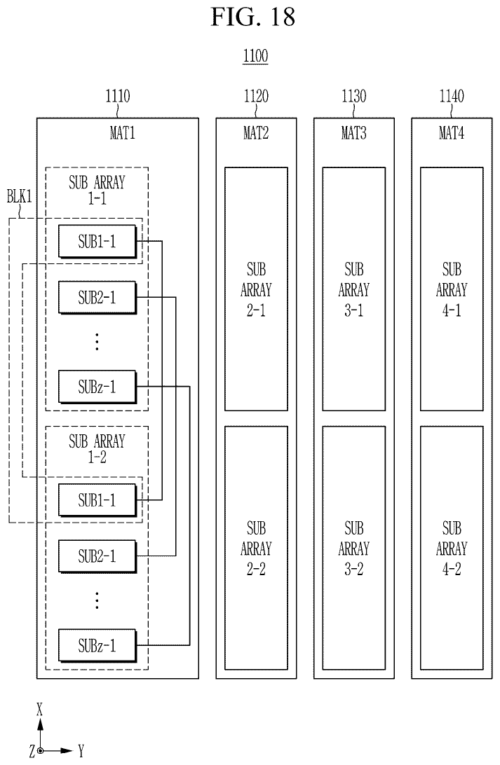

FIG. 18 is a diagram illustrating another example of a plurality of sub arrays including a plurality of memory blocks according to some implementations.

Referring to FIG. 18, a memory cell array 1100 may include a first mat 1110, a second mat 1120, a third mat 1130, and a fourth mat 1140. The first mat 1110 may include a 1-1 sub array SUB ARRAY1-1 and a 1-2 sub array SUB ARRAY1-2.

In some implementations, the 1-1 sub array SUB ARRAY1-1 and the 1-2 sub array SUB ARRAY1-2 may include a plurality of memory blocks BLK1 to BLKz. In some implementations, the 1-1 sub array SUB ARRAY1-1 and the 1-2 sub array SUB ARRAY1-2 may be spaced apart from each other by a specific distance along the X direction.

In some implementations, each of the 1-1 sub array SUB ARRAY1-1 and the 1-2 sub array SUB ARRAY1-2 may include a plurality of sub blocks. According to some implementations, the 1-1 sub array SUB ARRAY1-1 may include the 1-1 sub block SUB1-1 included in the first memory block BLK1. In some implementations, the 1-2 sub array SUB ARRAY1-2 may include a 1-2 sub block SUB1-2 included in the first memory block BLK1.

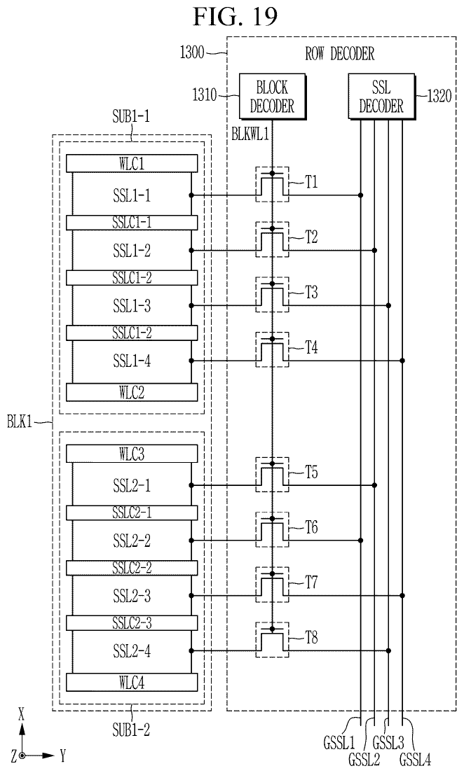

FIG. 19 is a diagram illustrating another example of a connection relationship between a plurality of sub blocks and a row decoder according to some implementations.

Referring to FIG. 19, the row decoder 1300 may include a block decoder 1310, a string selection line decoder 1320, a first transistor T1, a second transistor T2, a third transistor T3, a fourth transistor T4, a fifth transistor T5, a sixth transistor T6, a seventh transistor T7, and an eighth transistor T8.

In some implementations, the first transistor T1, the second transistor T2, the third transistor T3, the fourth transistor T4, the fifth transistor T5, the sixth transistor T6, the seventh transistor T7, and the eighth transistor T8 may be connected in common to the first block word line BLKWL1. The first block word line BLKWL1 may be a word line for selecting the first memory block BLK1.

In some implementations, the first transistor T1 may be connected to the 1-1 string selection line SSL1-1 and the first global string selection line GSSL1. The sixth transistor T6 may be connected to the first global string selection line GSSL1 and the 2-2 string selection line SSL2-2.

In some implementations, the second transistor T2 may be connected to the 1-2 string selection line SSL1-2 and the second global string selection line GSSL2. The fifth transistor T5 may be connected to the second global string selection line GSSL2 and the 2-1 string selection line SSL2-1.

In some implementations, the third transistor T3 may be connected to the 1-3 string selection line SSL1-3 and the third global string selection line GSSL3. The eighth transistor T8 may be connected to the third global string selection line GSSL3 and the 2-4 string selection line SSL2-4.

In some implementations, the fourth transistor T4 may be connected to the 1-4 string selection line SSL1-4 and the fourth global string selection line GSSL4. The seventh transistor T7 may be connected to the fourth global string selection line GSSL4 and the 2-3 string selection line SSL2-3.

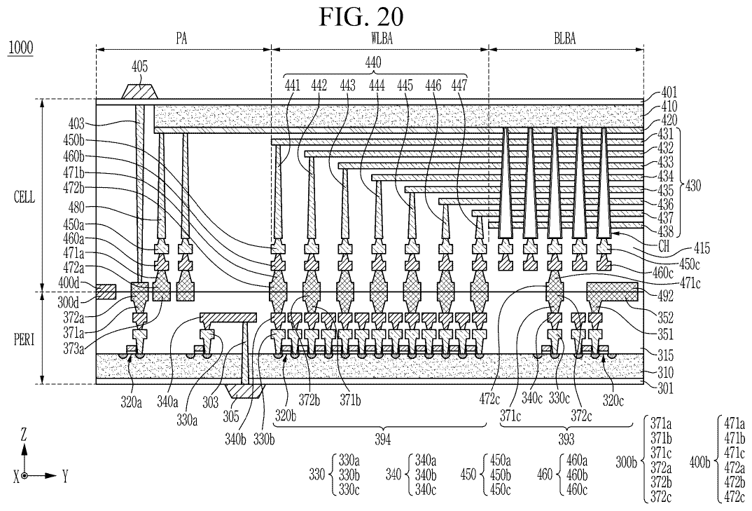

FIG. 20 is a cross-sectional view illustrating a non-volatile memory device having a B-VNAND (Bonding Vertical NAND) structure according to some implementations.

Referring to FIG. 20, the cell region CELL may correspond to the memory cell array 1100 of FIG. 1. The peripheral circuit region PERI may correspond to the voltage generator 1200, the row decoder 1300, the page buffer group 1400, and the control logic 1500 of FIG. 1.

In some implementations, the wiring layers 330a, 330b, and 330c are included in the wiring layer 330, and the wiring layers 340a, 340b, and 340c are included in the wiring layer 340. The wiring layers 450a, 450b, and 450c are included in the wiring layer 450, and the wiring layers 460a, 460b, and 460c are included in the wiring layer 460. In addition, the first bonding pads 371a, 372a, 371b, 372b, 371c, and 372c are configured to be included in the first bonding pad 300b, and the second bonding pads 471a, 472a, 471b, 472b, 471c, and 472c are configured to be included in the second bonding pad 400b.

In some implementations, the peripheral circuit region PERI may include a first substrate 310, an interlayer insulating layer 315, a plurality of circuit elements 320a, 320b, and 320c formed on a first substrate 310, first wiring layers 330a, 330b, and 330c connected to a plurality of circuit elements 320a, 320b, and 320c, respectively, and second wiring layers 340a, 340b, and 340c formed on the first wiring layers 330a, 330b, and 330c. In some implementations, the first wiring layers 330a, 330b, and 330c may be formed of tungsten having a relatively high resistance, and the second wiring layers 340a, 340b, and 340c may be formed of copper having a relatively low resistance.

In some implementations, the interlayer insulating layer 315 is disposed on the first substrate 310 to cover a plurality of circuit elements 320a, 320b and 320c, the first wiring layers 330a, 330b and 330c, and the second wiring layers 340a, 340b and 340c, and may include an insulating material such as silicon oxide or silicon nitride.

In some implementations, lower bonding pads 371b and 372b may be formed on the second wiring layer 340b of the word line bonding area WLBA. In the word line bonding area WLBA, the lower bonding pads 371b and 372b of the peripheral circuit region PERI may be electrically connected to the upper bonding pads 471b and 472b of the cell area CELL by a bonding method, and the lower bonding pads 371b and 372b and the upper bonding pads 471b and 472b may be formed of aluminum, copper, tungsten, or the like.

In some implementations, the cell region CELL may provide at least one memory block. The cell region CELL may include the second substrate 410 and a common source line 420. On the second substrate 410, a plurality of word lines 430 (431 to 438) may be stacked along the Z axis direction perpendicular to the upper surface of the second substrate 410. String selection lines and a ground selection line may be arranged at each of the upper and lower portions of the plurality of word lines 430, and a plurality of word lines 430 may be arranged between the string selection lines and the ground selection line.

In some implementations, in the bit line bonding area BLBA, the channel hole CH may extend in a direction perpendicular to the upper surface of the second substrate 410 and penetrate a plurality of word lines 430, string selection lines, and ground selection lines. The channel hole CH may include a data storage layer, a channel layer, a buried insulating layer, and the like, and the channel layer may be electrically connected to the first wiring layer 450c and the second wiring layer 460c. In some implementations, the first wiring layer 450c may be a bit line contact, and the second wiring layer 460c may be a bit line. In some implementations, the bit line 460c may extend in an X direction parallel to the top surface of the second substrate 410.

In some implementations, an area in which the channel hole CH, the bit line 460c, and the like are disposed may be defined as a bit line bonding area BLBA. The bit line 460c may be electrically connected to the circuit elements 320c providing the page buffer 393 in the peripheral circuit region PERI in the bit line bonding area BLBA. In some implementations, the bit line 460c may be connected to the upper bonding pads 471c and 472c in the peripheral circuit region PERI, and the upper bonding pads 471c and 472c may be connected to the lower bonding pads 371c and 372c connected to the circuit elements 320c of the page buffer 393.

In some implementations, in the word line bonding area WLBA, a plurality of word lines 430 may extend along the Y direction parallel to the upper surface of the second substrate 410 and may be connected to a plurality of cell contact plugs 441 to 447. A plurality of word lines 430 and cell contact plugs 440 may be connected to each other at pads provided by extending at least some of the word lines 430 with different lengths along the Y direction. A first wiring layer 450b and a second wiring layer 460b may be sequentially connected to an upper portion of the cell contact plugs 440 connected to a plurality of word lines 430. The cell contact plugs 440 may be connected to the peripheral circuit region PERI through the upper bonding pads 471b and 472b of the cell region CELL and the lower bonding pads 371b and 372b of the peripheral circuit region PERI in the word line bonding area WLBA.

In some implementations, the cell contact plugs 440 may be electrically connected to circuit elements 320b that provide the row decoder 394 in the peripheral circuit region PERI. In some implementations, the operating voltage of the circuit elements 320b providing the row decoder 394 may be different from the operating voltage of the circuit elements 320c providing the page buffer 393.

In some implementations, a common source line contact plug 480 may be disposed in the external pad bonding area PA. The common source line contact plug 480 is formed of a conductive material such as a metal, a metal compound, or polysilicon, and may be electrically connected to the common source line 420. A first wiring layer 450a and a second wiring layer 460a may be sequentially stacked on the common source line contact plug 480. In some implementations, an area in which the common source line contact plug 480, the first wiring layer 450a, and the second wiring layer 460a are disposed may be defined as an external pad bonding area PA.

In some implementations, input/output pads 305 and 405 may be disposed in the external pad bonding area PA. A lower insulation layer 301 covering a lower surface of the first substrate 310 may be formed under the first substrate 310, and a first input/output pad 305 may be formed on the lower insulation layer 301. The first input/output pad 305 is connected to at least one of a plurality of circuit elements 320a, 320b, and 320c disposed in the peripheral circuit region PERI through the first input/output contact plug 303 and may be separated from the first substrate 310 by a lower insulation layer 301. In addition, a side insulation layer may be placed between the first input/output contact plug 303 and the first substrate 310 to electrically separate the first input/output contact plug 303 and the first substrate 310.

In some implementations, an upper insulation layer 401 covering an upper surface of the second substrate 410 may be formed on an upper portion of the second substrate 410, and a second input/output pad 405 may be disposed on the upper insulation layer 401. The second input/output pad 405 may be connected to at least one of a plurality of circuit elements 320a, 320b, and 320c disposed in the peripheral circuit region PERI through the second input/output contact plug 403.

In some implementations, the second substrate 410, the common source line 420, and the like may not be disposed in an area in which the second input/output contact plug 403 is disposed. Also, the second input/output pad 405 may not overlap the word lines 430 in the Z direction. The second input/output contact plug 403 may be separated from the second substrate 410 in a direction parallel to the upper surface of the second substrate 410 and may be connected to the second input/output pad 405 through the interlayer insulation layer 415 in the cell region CELL.

In some implementations, the first input/output pad 305 and the second input/output pad 405 may be selectively formed. In some implementations, the non-volatile memory device 1000 may include only the first input/output pad 305 disposed on the first substrate 301 or only the second input/output pad 405 disposed on the second substrate 401.

In some implementations, a wiring pattern of an uppermost wiring layer may exist in each of the external pad bonding area PA and the bit line bonding area BLBA included in each of the cell area CELL and the peripheral circuit region PERI as a dummy pattern, or the uppermost wiring layer may be empty.

In some implementations, in an external pad bonding area PA of a non-volatile memory device 1000, a lower wiring pattern 373a having the same shape as the upper wiring pattern 472a of the cell region CELL may be formed in an upper wiring layer of a peripheral circuit region PERI corresponding to the upper wiring pattern 472a formed in the upper wiring layer of the cell region CELL. The lower wiring pattern 373a formed on the uppermost wiring layer of the peripheral circuit region PERI may not be connected to a separate contact in the peripheral circuit region PERI. In some implementations, an upper wiring pattern having the same shape as the lower wiring pattern of the peripheral circuit region PERI may be formed on the upper wiring layer of the cell region CELL to correspond to the lower wiring pattern formed on the uppermost wiring layer of the peripheral circuit region PERI in the external pad bonding area PA.

In some implementations, lower bonding pads 371b and 372b may be formed on the second wiring layer 340b of the word line bonding area WLBA. In the word line bonding area WLBA, the lower bonding pads 371b and 372b of the peripheral circuit region PERI may be electrically connected to the upper bonding pads 471b and 472b of the cell area CELL by a bonding method.

In some implementations, in the bit line bonding area BLBA, an upper wiring pattern 492 having the same shape as the lower wiring pattern 352 of the peripheral circuit region PERI can be formed in the upper wiring layer of the cell area CELL corresponding to the lower wiring pattern 352 formed in the upper wiring layer of the peripheral circuit region PERI. A contact may not be formed on the upper wiring pattern 492 formed on the uppermost wiring layer of the cell region CELL.

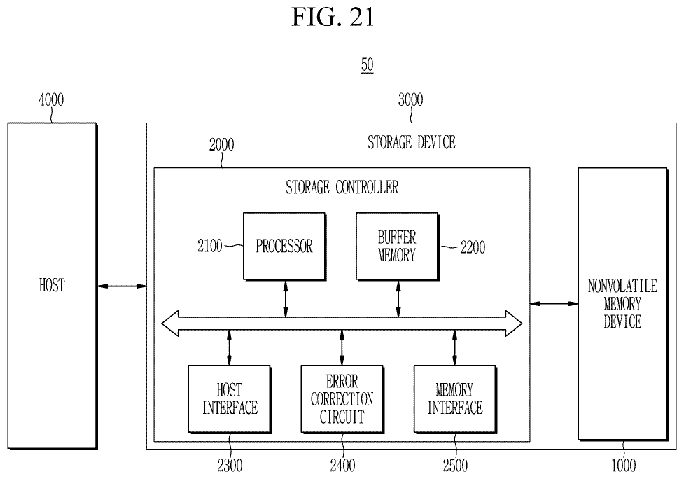

FIG. 21 is a drawing for explaining a storage device including a non-volatile memory device according to some implementations.

Referring to FIG. 21, an electronic system 50 may include a storage device 3000 and a host 4000.

The storage device 3000 may be a device that stores data under the control of the host 4000. In some implementations, the storage device 3000 may be manufactured in the form of a solid state drive SSD or a universal flash storage UFS.

The storage device 3000 may include a non-volatile memory device 1000 and a storage controller 2000.

The non-volatile memory device 1000 may store data. The non-volatile memory device 1000 may operate in response to the control of the storage controller 2000. In some implementations, the non-volatile memory device 1000 may be a NAND flash memory. The non-volatile memory device 1000 may include a plurality of planes. Each of the plurality of planes may include a plurality of memory blocks. Each of the plurality of memory blocks may include a plurality of memory cells.

The non-volatile memory device 1000 may receive a command and an address from the storage controller 2000 and may perform an operation indicated by the command on an area selected by the address. The non-volatile memory device 1000 may perform a program operation (a write operation) of storing data in an area selected by an address, a read operation of reading data, or an erase operation of deleting data.

The storage controller 2000 may control the overall operation of the storage device 3000.

In some implementations, the storage controller 2000 may execute firmware when power is applied to the storage device 3000. The firmware may include a host interface layer that controls communication with the host 4000, a flash conversion layer that controls communication between the host 4000 and the non-volatile memory device 1000, and a memory interface layer that controls communication with the non-volatile memory device 1000. In some implementations, the flash conversion layer may convert a logical address of the host 4000 into a physical address of the non-volatile memory device 1000.

In some implementations, the flash conversion layer may convert a logical address of the host 4000 into a physical address of the non-volatile memory device 1000. The storage controller 2000 may provide a write command, an address, and data to the non-volatile memory device 1000 during a write operation. The storage controller 2000 may provide a read command and an address to the non-volatile memory device 1000 during a read operation. The storage controller 2000 may provide an erase command and an address to the non-volatile memory device 1000 during an erase operation.

In some implementations, the storage controller 2000 may include a processor 2100, a buffer memory 2200, a host interface 2300, an error correction circuit 2400, and a memory interface 2500.

The processor 2100 may control the overall operation of the storage controller 2000. The processor 2100 may control the operation of the storage controller 2000 to store data requested from the host 4000 in the non-volatile memory device 1000.

The buffer memory 2200 may be used as a buffer memory, a cache memory, an operation memory, or the like of the storage controller 2000.

The buffer memory 2200 may temporarily store data provided from the host 4000 or may temporarily store data read from the non-volatile memory device 1000. In some implementations, the buffer memory 2200 may be a dynamic random access memory DRAM or a static random access memory SRAM.

The host interface 2300 may communicate with the host 4000. The host interface 2300 may receive data from the host 4000 or may provide data to the host 4000.

The error correction circuit 2400 may perform an error correction operation. In some implementations, the error correction circuit 2400 may perform error correction encoding on data to be stored in the non-volatile memory device 1000 through the memory interface 2500. The error correction encoded data may be transmitted to the non-volatile memory device 1000 through the memory interface 2500. In some implementations, the error correction circuit 2400 may perform error correction decoding on data received from the non-volatile memory device 1000.

The memory interface 2500 may communicate with the non-volatile memory device 1000. The memory interface 2500 may provide a command, an address, and data to the non-volatile memory device 1000. The memory interface 2500 may receive data stored in the non-volatile memory device 1000.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the disclosure have been described in detail above, the scope of the present disclosure is not limited to the scope of the present disclosure, but various modifications and improvements of the person of an order skill in the art using the basic concept of the present disclosure defined in the following claim range also belong to the scope of the present disclosure.

What is claimed is:

1. A memory device comprising:
a first sub array comprising a first word line cut, a second word line cut, and a plurality of first string selection line cuts positioned between the first word line cut and the second word line cut, wherein the plurality of first string selection line cuts includes a first-sub-array first string selection line cut and a first-sub-array second string selection line cut; and
a second sub array comprising a third word line cut, a fourth word line cut, and a plurality of second string selection line cuts positioned between the third word line cut and the fourth word line cut, wherein the plurality of second string selection line cuts include a second-sub-array first string selection line cut and a second-sub-array second string selection line cut,
wherein the first sub array comprises:
a first-sub-array first string selection line that is positioned between the first word line cut and the first-sub-array first string selection line cut, the first-sub-array first string selection line cut being spaced apart by a first length from the first word line cut, and
a first-sub-array second string selection line that is positioned between the first-sub-array first string selection line cut and the first-sub-array second string selection line cut, the first-sub-array second string selection line cut being spaced farther apart from the first word line cut than from the first-sub-array first string selection line cut, and
wherein the second sub array comprises:
a second-sub-array first string selection line that is positioned between the second-sub-array first string selection line cut and the second-sub-array second string selection line cut, the second-sub-array first string selection line cut being spaced apart by a second length from the third word line cut, and the second-sub-array second string line cut being spaced farther apart from the third word line cut than from the second-sub-array first string selection line, wherein the second-sub-array first string selection line is connected to the first-sub-array first string selection line, and
a second-sub-array second string selection line that is positioned between the third word line cut and the second-sub-array first string selection line cut, wherein the second-sub-array second string selection line is connected to the first-sub-array the second string selection line.

2. The memory device of claim 1,
wherein the first sub array comprises:
a first-sub-array third string selection line that is positioned between the first-sub-array second string selection line cut and the second word line cut of the first sub array, and
wherein the second sub array comprises:
a second-sub-array third string selection line that is positioned between the second-sub-array second string selection line cut and the fourth word line cut of the second sub array, wherein the second-sub-array third string selection line is connected to the first-sub-array third string selection line.

3. The memory device of claim 1,
wherein the plurality of first string selection line cuts includes a first-sub-array third string selection line cut,
wherein the plurality of second string selection line cuts includes a second-sub-array third string selection line cut,
wherein the first sub array comprises:
a first-sub-array third string selection line that is positioned between the first-sub-array second string selection line cut and the first-sub-array third string selection line cut, the first-sub-array third string selection cut being spaced apart by the first length from the second word line cut, and
wherein the second sub array comprises:
a second-sub-array third string selection line that is positioned between the second-sub-array third string selection line cut and the fourth word line cut of the second sub array, the second-sub-array third string selection line cut being spaced apart by the first length from the fourth word line cut, wherein the second-sub-array third string selection line is connected to the first-sub-array third string selection line.

4. The memory device of claim 3,
wherein the first sub array comprises:
a first-sub-array fourth string selection line that is positioned between the first-sub-array third string selection line cut and the second word line cut of the first sub array, and
wherein the second sub array comprises:
a second-sub-array fourth string selection line that is positioned between the second-sub-array second string selection line cut and the second-sub-array third string selection line cut, wherein the second-sub-array fourth string selection line is connected to the first-sub-array fourth string selection line.

5. The memory device of claim 1,
wherein the first sub array comprises:
a first-sub-array third string selection line that is positioned between the first-sub-array second string selection line cut and the first-sub-array third string selection line cut, wherein the first-sub-array third string selection line cut is spaced farther apart from the first word line cut than from the first-sub-array second string selection line cut, and
wherein the second sub array comprises:
a second-sub-array third string selection line that is positioned between the second-sub-array third string selection line cut and the fourth word line cut, the second-sub-array third string selection line cut being spaced apart from the fourth word line cut by the first length, wherein the second-sub-array third string selection line is connected to the first-sub-array third string selection line.

6. The memory device of claim 5,
wherein the plurality of first string selection line cuts includes a first-sub-array fourth string selection line cut,
wherein the plurality of second string selection line cuts includes a second-sub-array fourth string selection line cut,
wherein the first sub array comprises:
a first-sub-array fourth string selection line that is positioned between the first-sub-array third string selection line cut and the first-sub-array fourth string selection line cut, the first-sub-array fourth string selection line cut being spaced apart from the second word line cut by the first length, and
wherein the second sub array comprises:
a second-sub-array fourth string selection line that is positioned between the second-sub-array first string selection line cut and the second-sub-array fourth string selection line cut, the second-sub-array fourth string selection line cut being closer to the fourth word line cut than the second-sub-array first string selection line cut, wherein the second-sub-array fourth string selection line is connected to the first-sub-array fourth string selection line.

7. The memory device of claim 6,
wherein the first sub array comprises:
a first-sub-array fifth string selection line that is positioned between the first-sub-array fourth string selection line cut and the second word line cut, and
wherein the second sub array comprises:
a second-sub-array fifth string selection line that is positioned between the second-sub-array second string selection line cut and the second-sub-array third string selection line cut, wherein the second-sub-array fifth string selection line is connected to the first-sub-array fifth string selection line.

8. The memory device of claim 1, comprising:
a third sub array comprising a fifth word line cut, a sixth word line cut, and a plurality of third string selection line cuts positioned between the fifth word line cut and the sixth word line cut, wherein the plurality of third string selection line cuts includes a third-sub-array first string selection line cut and a third-sub-array second string selection line cut; and
a fourth sub array comprising a seventh word line cut, an eighth word line cut, and a plurality of fourth string selection line cuts positioned between the seventh word line cut and the eighth word line cut, wherein the plurality of fourth string selection line cuts includes a fourth-sub-array first string selection line cut and a fourth-sub-array second string selection line cut,
wherein the third sub array comprises:
a third-sub-array first string selection line that is positioned between the third-sub-array first string selection line cut and the third-sub-array second string selection line cut, the third-sub-array first string selection line cut being spaced apart from the fifth word line cut by a third length, and the third-sub-array second string selection line cut being spaced apart from the fifth word line cut by a fourth length greater than the third length, wherein the third-sub-array first string selection line is connected to the second-sub-array first string selection line, and
wherein the fourth sub array comprises:
a fourth-sub-array first string selection line that is positioned between the fourth-sub-array third string selection line cut and the fourth-sub-array second string selection line cut, the fourth-sub-array third string selection line cut being spaced apart from the seventh word line cut by the fourth length, the fourth-sub-array second string selection line cut being spaced apart from the seventh word line cut by a fifth length greater than the fourth length, wherein the fourth-sub-array first string selection line is connected to the third-sub-array first string selection line.

9. The memory device of claim 1, comprising:
a first transistor connected to a block word line that is configured to select a first memory block, the first memory block comprising the first sub array and the second sub array, the first transistor being connected to the first-sub-array first string selection line and the second-sub-array first string selection line; and
a second transistor connected to the block word line and connected to the first-sub-array second string selection line and the second-sub-array second string selection line.

10. The memory device of claim 1, comprising:
a plurality of global string selection lines including a first global string selection line and a second global string selection line,
wherein the first global string selection line is connected to the first-sub-array first string selection line and the second-sub-array first string selection line, and
wherein the second global string selection line is connected to the first-sub-array second string selection line and the second-sub-array second string selection line.

11. A memory device comprising:
a first word line cut;
a second word line cut;
a third word line cut;
a fourth word line cut;
a first sub array comprising:
a first-sub-array first string selection line that is positioned between the first word line cut and the second word line cut, the first-sub-array first string selection line being spaced apart from an adjacent one of the first word line cut and the second word line cut by a first length;
a first-sub-array second string selection line that is positioned between the first word line cut and the second word line cut, the first-sub-array second string line being spaced apart from an adjacent one of the first word line cut and the second word line cut by a second length greater than the first length;
a second sub array comprising:
a second-sub-array first string selection line that is positioned between the third word line cut and the fourth word line cut, the second-sub-array first string selection line being spaced apart from an adjacent one of the third word line cut and the fourth word line cut by the second length, wherein the second-sub-array first string selection line is connected to the first-sub-array first string selection line; and
a second-sub-array second string selection line that is positioned between the third word line cut and the fourth word line cut, the second-sub-array second string selection line being spaced apart from an adjacent one of the third word line cut and the fourth word line cut by the first length, wherein the second-sub-array second string selection line is connected to the first-sub-array second string selection line.

12. The memory device of claim 11, comprising:
a first-sub-array third string selection line is positioned between the first word line cut and the second word line cut, the first-sub-array third string selection line being spaced apart from the second word line cut by the first length; and
a second-sub-array third string selection line that is positioned between the third word line cut and the fourth word line cut, the second-sub-array third string selection line being spaced apart from the third word line cut by the first length, wherein the second-sub-array third string selection line is connected to the first-sub-array third string selection line.

13. The memory device of claim 11, comprising:
a first-sub-array third string selection line that is positioned between the first word line cut and the second word line cut, the first-sub-array third string selection line being spaced apart from the first word line cut by the second length; and
a second-sub-array third string selection line that is positioned between the third word line cut and the fourth word line cut, the second-sub-array third string selection line being spaced apart from the third word line cut by the first length, wherein the second-sub-array third string selection line is connected to the first-sub-array third string selection line.

14. The memory device of claim 13, comprising:
a first-sub-array fourth string selection line that is positioned between the first word line cut and the second word line cut, the first-sub-array fourth string selection line being spaced apart from the second word line cut by the first length; and
a second-sub-array fourth string selection line that is positioned between the third word line cut and the fourth word line cut, the second-sub-array fourth string selection line being spaced apart from the fourth word line cut by the second length, wherein the second-sub-array fourth string selection line is connected to the first-sub-array fourth string selection line.

15. The memory device of claim 13, comprising:
a first-sub-array fourth string selection line that is positioned between the first word line cut and the second word line cut, the first-sub-array fourth string selection line being spaced apart from the second word line cut by the second length;
a first-sub-array fifth string selection line that is positioned between the first word line cut and the second word line cut, the first-sub-array fifth string selection line being spaced apart from the second word line cut by the first length;
a second-sub-array fourth string selection line that is positioned between the third word line cut and the fourth word line cut, the second-sub-array fourth string selection line being spaced apart from the third word line cut by the second length, wherein the second-sub-array fourth string selection line is connected to the first-sub-array fourth string selection line; and
a second-sub-array fifth string selection line that is positioned between the third word line cut and the fourth word line cut, the second-sub-array fifth string selection line being spaced apart from the fourth word line cut by the second length, wherein the second-sub-array fifth string selection line is connected to the first-sub-array fifth string selection line.

16. The memory device of claim 11, comprising:
a first-sub-array third string selection line that is positioned between the first word line cut and the second word line cut, the first-sub-array third string selection line being spaced apart from the first word line cut by the second length;
a first-sub-array fourth string selection line that is positioned between the first word line cut and the second word line cut, the first-sub-array fourth string selection line being spaced apart from the first word line cut by a third length greater than the second length;
a first-sub-array fifth string selection line that is positioned between the first word line cut and the second word line cut, the first-sub-array fifth string selection line being spaced apart from the second word line cut by the third length;
a first-sub-array sixth string selection line that is positioned between the first word line cut and the second word line cut, the first-sub-array sixth string selection line being spaced apart from the second word line cut by the first length;
a second-sub-array third string selection line that is positioned between the third word line cut and the fourth word line cut, the second-sub-array third string selection line being spaced apart from the third word line cut by the second length, wherein the second-sub-array third string selection line is connected to the first-sub-array third string selection line;
a second-sub-array fourth string selection line that is positioned between the third word line cut and the fourth word line cut, the second-sub-array fourth string selection line being spaced apart from the third word line cut by the first length, wherein the second-sub-array fourth string selection line is connected to the first-sub-array fourth string selection line;
a second-sub-array fifth string selection line that is positioned between the third word line cut and the fourth word line cut, the second-sub-array fifth string selection line being spaced apart from the fourth word line cut by the second length, wherein the second-sub-array fifth string selection line is connected to the first-sub-array fifth string selection line; and
a second-sub-array sixth string selection line that is positioned between the third word line cut and the fourth word line cut, the second-sub-array sixth string selection line being spaced apart from the fourth word line cut by the third length, wherein the second-sub-array sixth string selection line is connected to the first-sub-array sixth string selection line.

17. The memory device of claim 11, comprising:
a fifth wordline cut;
a sixth wordline cut;
a seventh wordline cut;
an eighth wordline cut;
a third-sub-array first string selection line that is positioned between the fifth word line cut and the sixth word line cut, the third-sub-array first string selection line being spaced apart from the fifth word line cut by a third length that is greater than the second length, wherein the third-sub-array first string selection line is connected to the first-sub-array first string selection line and the second-sub-array first string selection line; and
a fourth-sub-array first string selection line that is positioned between the seventh word line cut and the eighth word line cut, the fourth-sub-array first string selection line being spaced apart from the seventh word line cut by a fourth length greater than the third length, wherein the fourth-sub-array first string selection line is connected to the third-sub-array first string selection line.

18. The memory device of claim 11, comprising:
a first global string selection line connected to the first-sub-array first string selection line and the second-sub-array first string selection line; and
a second global string selection line connected to the first-sub-array second string selection line and the second-sub-array second string selection line.

19. A memory device comprising:
a first sub array comprising a first word line cut, a second word line cut, and a plurality of first-sub-array string selection lines positioned between the first word line cut and the second word line cut, wherein the plurality of first-sub-array string selection lines includes a first-sub-array first string selection line and a first-sub-array second string selection line, the first-sub-array first string selection line being adjacent to the first word line cut; and
a second sub array comprising a third word line cut, a fourth word line cut, and a plurality of second-sub-array string selection lines positioned between the third word line cut and the fourth word line cut, wherein the plurality of second-sub-array string selection lines includes a second-sub-array first string selection line and a second-sub-array second string selection line;
wherein each of the plurality of first-sub-array string selection lines is connected to each of the plurality of second-sub-array string selection lines, and
wherein a first sum of (i) a first length between the first-sub-array first string selection line and the first word line cut and (ii) a second length between the second-sub-array first string selection line connected to the first-sub-array first string selection line and an adjacent one of the third word line cut and the fourth word line cut is a same as a second sum of (iii) a third length between the first-sub-array second string selection line and an adjacent one of the first word line cut and the second word line cut and (iv) a fourth length between the second-sub-array second string selection line connected to the first-sub-array second string selection line and an adjacent one of the third word line cut and the fourth word line cut.

20. The memory device of claim 19,
wherein the plurality of first-sub-array string selection lines includes a first-sub-array third string selection line,
wherein the plurality of second-sub-array string selection lines includes a second-sub-array third string selection line,
wherein a difference between:
(A) a third sum of (i) a fifth length between the first-sub-array third string selection line and an adjacent one of the first word line cut and the second word line cut and (ii) a sixth length between the second-sub-array third string selection line connected to the first-sub-array third string selection line and an adjacent one of the third word line cut and the fourth word line cut, and
(B) the first sum of the first length and the second length
corresponds to a fourth sum of (iii) a seventh length between the first-sub-array first string selection line cut adjacent to the first first-sub-array string selection line and the first word line cut and (iv) an eighth length of the first-sub-array first string selection line cut.
